(19) United States
(12) Patent Application Publication
(10) Pub. No.: US 2026/0321954 A1
(43) Pub. Date: Oct. 15, 2026

(54) Multi-Mode Microwave Resonator Devices for Electron Spin Resonance

(71) Applicant: Quantum Valley Investment Fund LP, Waterloo (CA)

(72) Inventors: Hamidreza Mohebbi, Waterloo (CA); Troy W. Borneman, Waterloo (CA)

(73) Assignee: Quantum Valley Investment Fund LP, Waterloo (CA)

(21) Appl. No.: 19/698,174

(22) Filed: Jun. 4, 2026

Related U.S. Application Data
(63) Continuation of application No. PCT/CA2023/051755, filed on Dec. 22, 2023.

(51) Int. Cl. H01P 7/08; G01N 24/12

(52) U.S. Cl. CPC H01P 7/082; G01N 24/12

(57) ABSTRACT

In a general aspect, a microwave resonator device for electron spin resonance is described. In some aspects, a microwave resonator device for electron spin resonance includes a substrate, a ground plane on the substrate; and a plurality of conductors that support a plurality of microwave resonant modes in a sample region of the microwave resonator device. The plurality of conductors are disposed on the substrate and include a first transmission line resonator; and a second transmission line resonator, which is coupled to the first transmission line resonator.

### BACKGROUND

The following description relates to a multi-mode microwave resonator device for electron spin resonance.

This specification relates to a microwave resonator device for magnetic resonance applications, including electron spin resonance (ESR) applications. Electron spin resonance systems are used to study various types of samples and phenomena. In some magnetic resonance applications, the spins in a sample are polarized by a static, external magnetic field, and a resonator manipulates the spins by producing a magnetic field at a frequency near the spins' resonance frequencies. In electron spin resonance (ESR) applications, resonators typically operate at microwave frequencies to interact with electron spins in the sample.

### DESCRIPTION OF DRAWINGS

FIG. 1 is a schematic diagram showing aspects of an example electron spin resonance (ESR) system.

FIG. 2 is a circuit diagram showing an equivalent circuit model of an example microwave resonator device.

FIG. 3A is a circuit diagram showing an equivalent circuit model of an example microwave resonator device.

FIG. 3B is a circuit diagram showing an equivalent circuit model of an example symmetric microwave resonator device.

FIG. 3C includes circuit diagrams showing two operation modes of the equivalent circuit model shown in FIG. 3B.

FIG. 3D is a plot showing resonance frequencies in GHz as a function of the transmission line length I in mm in the microwave resonator device represented by the equivalent circuit model shown in FIG. 3B.

FIG. 4A is a circuit diagram showing an equivalent circuit model of an example microwave resonator device.

FIG. 4B is a circuit diagram showing an equivalent circuit model of an example symmetric microwave resonator device.

FIG. 4C includes circuit diagrams showing two operation modes of the equivalent circuit model shown in FIG. 4B.

FIG. 4D is a plot showing resonance frequencies in GHz as a function of the transmission line length I in mm in the microwave resonator device represented by the equivalent circuit model shown in FIG. 4B.

FIG. 5A is a circuit diagram showing an equivalent circuit model of an example microwave resonator device.

FIG. 5B is a circuit diagram showing an equivalent circuit model of an example symmetric microwave resonator device.

FIG. 5C includes circuit diagrams showing two operation modes of the equivalent circuit model shown in FIG. 5B.

FIG. 5D includes plots showing S-parameters (S11, S21) in dB as a function of frequency in GHz at different coupling capacitance values Cₛ of the microwave resonator device represented by the equivalent circuit model shown in FIG. 5B at a constant coupling resonator electrical length of 180 degrees.

FIG. 5E includes plots showing S-parameters (S11, S21) in dB as a function of frequency in GHz at a constant coupling capacitance value Cₛ of 10 fF at different electrical lengths 0 of the third transmission line in the microwave resonator device represented by the equivalent circuit model shown in FIG. 5B.

FIG. 6 is a schematic diagram showing aspects of an example microwave resonator device.

FIG. 7A includes a plot showing S-parameters (S21) in dB as a function of frequency in GHz at different lengths of the coupling transmission line resonator in the microwave resonator device shown in FIG. 6; and a plot showing frequency in GHz as a function of the length of the coupling transmission line resonator in the microwave resonator device shown in FIG. 6 at different microwave resonant modes.

FIG. 7B includes plots showing a spatial distribution of a microwave magnetic field in the microwave resonator device shown in FIG. 6 with a constant coupling transmission line resonator of 9.9 mm.

FIG. 8 is a schematic diagram showing aspects of an example microwave resonator device.

FIG. 9 is a plot showing S-parameters (S21 and S11) in dB as a function of frequency in GHz of the microwave resonator device shown in FIG. 8.

FIG. 10A is a circuit diagram showing an equivalent circuit model of an example microwave resonator device with capacitive coupling.

FIG. 10B includes effective circuit diagrams showing modes of operation of an example microwave resonator device.

FIG. 11A is a circuit diagram showing an equivalent circuit model of an example microwave resonator device with inductive coupling.

FIG. 11B includes effective circuit diagrams showing modes of operation of an example microwave resonator device.

FIG. 12 is a schematic diagram showing aspects of an example microwave resonator device.

FIG. 13 is a plot showing S-parameters (S21) in dB as a function of frequency in GHz with the coupling gaps of the microwave resonator device shown in FIG. 12 at different sizes.

FIG. 14 is a flow chart showing aspects of an example process for operating an example microwave resonator device.

### DETAILED DESCRIPTION

In some aspects of what is described here, a microwave resonator device for electron spin resonance has multiple resonant modes. In some instances, the microwave resonator device can generate a drive magnetic field at multiple microwave resonance frequencies to manipulate the electron spins. In some implementations, the microwave resonator supports two or more microwave resonant modes that share a common spatial volume in a sample region of the microwave resonator device. The microwave resonator device can be implemented as a planar resonator with multiple conductors that support multiple microwave resonant modes for performing electron spin resonance measurement. The multiple conductors and a ground plane can be disposed on a substrate (e.g., on one side of a substrate, or on both sides of a substrate). The multiple conductors may include a first transmission line resonator and a second transmission line resonator coupled to the first transmission line resonator. In some cases, the techniques and system described here can be deployed in connection with continuous wave (CW) magnetic resonance (e.g., using CW electron paramagnetic resonance spectroscopy methodology), pulse magnetic resonance (e.g., using pulsed electron paramagnetic resonance spectroscopy methodology), or a combination of these.

In some cases, the microwave resonator device can electromagnetically interact with liquid samples, solid samples, liquid crystal samples, spin-labeled protein samples, or other types of samples to be measured or otherwise analyzed by an electron spin resonance system. Aspects of the systems and techniques described here can be adapted for various types of applications. For example, the systems and techniques described here may be used for structural biology measurements, for instance, to measure structural properties of proteins or protein complexes in a biological sample (e.g., a blood sample, a urine sample, a saliva sample, a sweat sample, or another type of biological sample). Such measurements can be useful in clinical applications, for example, diagnostics, treatments, pharmaceutical drug discovery/development and understanding the structure and function of membrane proteins, and other applications. As another example, an electron spin resonance system may include components that operate in a cryogenic environment (e.g., at 77 K, 4 K, or other cryogenic temperatures below 273 K), or an electron spin resonance system may operate at non-cryogenic temperatures including room temperatures.

In some implementations, the systems and techniques described here can provide a number of advantages. For example, the systems and techniques presented may enable multiple resonance measurements in pulsed EPR to examine the nature of multi-spin coupling networks in samples containing multiple unpaired electron spins. For instance, a specific microwave resonant mode can be dedicated for each pulse frequency allowing the quality factor (Q) of each mode to be increased, leading to a \sqrt{Q} increase in measurement signal-to-noise ratio. Additionally, the bandwidth and coupling factor of each microwave resonant mode may be optimized independently for each frequency in the pulse sequence to achieve higher Rabi drive strengths and more uniform response of pulses over a broader spectral range and to minimize correlated behavior between modes. The systems and methods presented here can in some cases improve SNR, modulation depth, and artifact suppression for multi-mode resonance measurements.

For another example, the systems and techniques described here can provide improved sensitivity due to an enhanced sample volume and low-loss behavior (high quality factor); and can provide sufficient bandwidth to perform double resonance, triple resonance, or other multiple resonance electron spin resonance measurements without introducing over-coupling or reducing the quality factor of the resonator. The systems and techniques described here may enable multi-mode resonance measurement of electron spins at higher quality while retaining uniform response, increased noise rejection, reduced microwave loss, and optimal Rabi drive strengths. In some cases, a combination of these and potentially other advantages and improvements may be obtained.

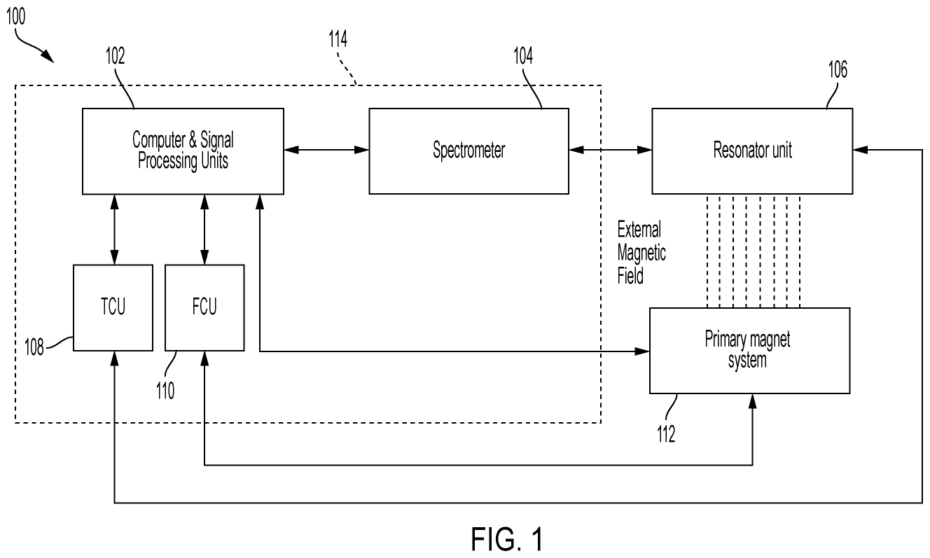

FIG. 1 is a schematic diagram showing aspects of an example electron spin resonance system 100. The example electron spin resonance system 100 includes a resonator unit 106, a primary magnet system 112, and a control system 114. The control system 114 further includes computer and signal processing units 102, a spectrometer unit 104, a temperature control unit (TCU) 108, and a field control unit (FCU) 110. In some examples, each of the units of the electron spin resonance system 100 may include an associated electronic circuit and other components, including housing, ports, etc.

In some cases, the computer and signal processing units 102 communicate with the spectrometer 104, the TCU 108, the FCU 110, the primary magnet system 114, and other units/components of the electron spin resonance system 100. In some instances, the computer and signal processing units 102 can be implemented as a single computer device (e.g., a laptop computer, a workstation, a desktop computer, a server) or by multiple computer devices. In some cases, the computer and signal processing units 102 can be co-located with the spectrometer 104, the resonator unit 106, and the other units or components of the example electron spin resonance system 100; and may be connected to other units and components of the electron spin resonance system 100, for example, by cables (e.g., coaxial cables, network cables, waveguides, etc.) or other types of local communication channels. In some cases, all or part of the computer and signal processing units 102 is located remotely from the spectrometer 104, and resonator unit 106, and may be directly connected to the units and components of the electron spin resonance system 100, for example, by a network (e.g., the Internet, a virtual private network, a wide area network, etc.) or other types of remote communication channels. Some aspects of the computer and signal processing units 102 may be deployed in a cloud computing environment, or otherwise. In some implementations, the computer and signal processing units 102 include one or more user interfaces such as, for example, a touchscreen, a pointing device, a keyboard, a microphone, etc., that allow a user to interact with and provide input to the computer and signal processing units 102 of the electron spin resonance system 100. In some implementations, the computer and signal processing units 102 include one or more user interface devices that allow the computer and signal processing units 102 to present information and data (e.g., graphical user interfaces, etc.) for display to a user.

The computer and signal processing units 102 can include, for example, a central processor unit (CPU) or another type of general-purpose processor that runs software. The computer and signal processing units 102 can include, for example, a graphics processing unit (GPU), a cryptographic processor unit, a field-programmable gate array (FPGA) unit, a digital signal processing (DSP) unit, or another type of data processing apparatus. In some instances, the computer and signal processing units 102 may be configured to perform digital signal processing and signal averaging. In particular, the computer and signal processing units 102 may be configured to identify a pulse sequence for an electron spin resonance experiment; generate sets of digital intermediate frequency (IF) signal information by modulating respective pulses in the pulse sequence at an intermediate frequency; generate a hardware control sequence based on the pulse sequence; convert the digital IF signal information and the hardware control sequence to the signal processing unit 104; generate digitized magnetic resonance detection signals; demodulate a digitized magnetic resonance detection signal at the intermediate frequency for phase-sensitive detection; etc. In some instances, the computer and signal processing units 102 may be configured to perform other operations. For example, the computer and signal processing units 102 may be configured to generate multiple resonance pulses by modulating pulses in a pulse sequence at different intermediate frequencies and superposing the modulated pulses, for example, for performing a multiple electron spin resonance measurement. In this case, the computer and signal processing units 102 may be also configured to demodulate the digitized magnetic resonance detection signal at the multiple intermediate frequencies. In some instances, the computer and signal processing units 102 may be controlled by software to execute a pre-configured program stored in a memory unit of the computer and signal processing units 102.

The computer and signal processing units 102 may be configured to generate analog electrical signals based on the digital signal values according to the hardware control sequence; and to transmit the analog electrical signals to the resonator unit 106 via the spectrometer 104. The computer and signal processing units 102 can further receive an electron spin resonance detection signal at a second resonance frequency from the resonator unit 106 via the spectrometer 104. The electron spin resonance detection signal includes a signal with amplitude, phase, and frequency modulation at an intermediate frequency and can be digitized by operation of the computer and signal processing units 102. In some instances, the computer and signal processing units 102 may be configured to perform other operations.

In some instances, the spectrometer 104 includes microwave or radio frequency hardware components (e.g., switches, mixers, amplifiers, attenuators, etc.) that manipulate microwave or radio frequency signals. For instance, the spectrometer 104 may be configured to process S-band (2-4 GHZ), C-band (4-8 GHZ), X-band (8-12 GHz), Ku-band signals (12-18 GHz), K-band signals (18-26.5 GHz), Q-band signals (33-50 GHz), V-band signals (50-75 GHz), W-band signals (75-110 GHz), or signals in other microwave frequency bands. In some examples, the spectrometer 104 may include a low phase noise microwave synthesizer to generate system master oscillator signals and analog spectrometer local oscillator signals, an IQ mixer device to upconvert analog IF electrical signals to single sideband signals that can be applied to the resonator unit 106 and to provide local oscillator suppression and image suppression, and a bandpass filter device to suppress noise bandwidth on a transmitter side. In some instances, the spectrometer 104 may include other circuit components. In certain cases, the spectrometer 104 can receive the analog IF electrical signals from the computer and signal processing units 102 and output a magnetic resonance control signal (e.g., upconverted and single band electrical signals). In some implementations, the magnetic resonance control signal has a frequency in a radio frequency or microwave regime. In the example shown in FIG. 1, the magnetic resonance control signal from the spectrometer 104 is passed to the resonator unit 106.

In some instances, the spectrometer 104 can be digitally controlled by the digital control signals from the computer and signal processing units 102. In some instances, the spectrometer 104 may include one or more switch devices. In some implementations, at least a portion of the spectrometer 104 operates in an elevated temperature, e.g., room temperature, outside of a cryogenic environment. In some instances, some components of the spectrometer 104 may operate at a cryogenic environment, for example, the same or different cryogenic environment where the resonator unit 106 resides. In some examples, the spectrometer 104 may be digitally controlled to perform fast switching between pulse and continuous-wave modes of operation. In some instances, the spectrometer 104 may include other components or may be configured to perform other operations.

In some instances, the spectrometer 104 may include an amplifier device (e.g., a cryogenic LNA device). In some implementations, the spectrometer 104 can include a mixer device for down-converting electron spin resonance detection signals received from the resonator unit 106 to an intermediate frequency (fIF), by mixing the electron spin resonance detection signals with a local oscillator frequency (fLo). The spectrometer 104 may also include a filter device that removes unwanted frequency components, for example, a bandpass IF filter device that rejects frequencies near a frequency value of fLo-fir from the mixer device and suppresses noise outside the receiver bandwidth (+fIF). The spectrometer 104 may also include other components such as, for example, an IF amplifier device, a lowpass filter device, and other circuit components. In some instances, the spectrometer 104 may include various stages of filtering and amplification to reduce noise bandwidth. The spectrometer 104 shown in FIG. 1 can accept both low-level spin signal inputs and high-level pulse transient digitizing inputs. In some examples, the spectrometer 104 may be controlled to switch between modes of operation, for example, between an electron spin resonance measurement mode and a pulse transient digitizing/correcting mode.

In some instances, the spectrometer 104 may be configured to process S-band (2-4 GHz), C-band (4-8 GHz), X-band (8-12 GHz), Ku-band signals (12-18 GHz), K-band signals (18-26.5 GHZ), Q-band signals (33-50 GHz), V-band signals (50-75 GHz), W-band signals (75-110 GHz), or signals in other microwave frequency bands. For example, the spectrometer 104 may include a single stage of up-conversion or down-conversion with a single microwave synthesizer device that is configured to generate LO signals at respective microwave frequency bands. For another example, the spectrometer 104 may include two or more stages of up-conversion or down-conversion with two or more microwave synthesizer devices and two or more corresponding mixer devices.

In the example shown in FIG. 1, components of the spectrometer 104 are electromagnetically coupled to (e.g., by coaxial cables, waveguides, etc.), and adapted to communicate with the resonator unit 106. For example, the spectrometer 104 can be adapted to provide a voltage or current electrical signal that drives the resonator unit 106. In the example shown in FIG. 1, the spectrometer 104 can also acquire magnetic resonance data based on control signals delivered to the resonator unit 106. For example, the spectrometer 104 may receive electron spin resonance detection signals generated by an interaction between the resonator unit 106 and samples at the resonator unit 106 based on the electron spin resonance control signals received at the resonator unit 106.

In some implementations, the electron spin resonance system 100 includes a superheterodyne spectrometer system. Generally, a superheterodyne spectrometer generates electron spin resonance control signals by mixing intermediate frequency (IF) signals with local oscillator (LO) signals to produce a high frequency (e.g., RF or microwave) signal that can then be further processed and passed on to the resonator unit 106; a superheterodyne spectrometer processes high-frequency electron spin resonance detection signals (e.g., spin signals) from the resonator unit 106 by mixing the high-frequency signals with LO signals to produce an IF signal, which can then be further processed and digitized for analysis by the data processing apparatus 102.

Superheterodyne operation can allow for increased sensitivity, selectivity, and signal-to-noise ratio, among other advantages. By generating control information and processing detected signals at IF frequencies, superior control and data processing can be achieved in some cases. Also, by using one or more tunable local oscillators, the superheterodyne spectrometer can tune to multiple distinct spin resonance frequencies, making it a versatile system.

In some implementations, the resonator unit 106 includes a microwave resonator device that resides in a cryogenic environment (e.g., at 77 K, 4 K, or other cryogenic temperatures below 273 K), for example, in a cryostat. The microwave resonator device of the resonator unit 106 may include multiple planar transmission line resonators each of which has a resonance frequency in a range of 2 GHz to 90 GHz. In some examples, the microwave resonator device has multiple microwave resonant modes. In some implementations, the microwave resonator device includes a primary transmission line resonator and an auxiliary transmission line resonator. The primary and auxiliary transmission line resonators may be coupled to each other, for example, in series through a coupling network (e.g., a transmission line, or a reactive component), or in another manner. The primary transmission line resonator and the auxiliary transmission line resonator allow mixing or hybridization of independent microwave resonant modes to create a multi-mode structure that spans both resonators. The primary transmission line resonator may generate microwave magnetic fields (e.g., drive magnetic fields) in a sample region to allow exchange of magnetic field energy at two or more distinct frequencies according to the electron spin resonance control signals received at the microwave resonator device. In some instances, the auxiliary transmission line resonator does not directly interact with the sample in the sample region; and during operation it introduces one or more additional microwave resonant modes in the primary transmission line resonator. In some instances, the microwave resonator device includes multiple conductors and a ground plane disposed on a surface of a substrate. In some instances, each of the multiple conductors and the ground plane are patterned on the substrate as a microstrip, a microstrip line, a coplanar waveguide, or another type of transmission line pattern. In some implementations, the multiple conductors and the ground plane includes superconducting or normal conductive metal material. In some implementations, the primary transmission line resonator includes a subset of the multiple conductors, which are formed in an array of conductive segments. In some instances, the conductive segments in the primary transmission line resonator are arranged in parallel to one another with equal spacing between each neighboring pair of conductive segments. Each conductive segment in the primary transmission line resonator may be configured to resonate at the same microwave resonance frequency. Each of the conductive segments in the primary transmission line resonator can be implemented, for example, as a half-wave resonator, a full-wave resonator, or a multi-half-wave resonator. Each of the conductive segments in the primary transmission line resonator may be configured to provide maximum magnetic field at the center of each conductive segment, where a sample region of the microwave resonator device resides. In some instances, the primary transmission line resonator may be configured in another manner, e.g., a single microstrip line, or a coplanar waveguide. Similarly, the auxiliary transmission line resonator may be a single microstrip line, a coplanar waveguide, multiple microstrip lines, or another type of planar transmission line. In some implementations, the primary transmission line resonator has a first intrinsic resonance frequency; and the auxiliary transmission line resonator has a second intrinsic resonance frequency. In some instances, the first intrinsic resonance frequency may be identical to the second intrinsic resonance frequency. In certain cases, the first and second intrinsic resonance frequencies may have a detuning, e.g., the first intrinsic resonance frequency may be offset from the second intrinsic resonance frequency. In some implementations, resonance frequencies and frequency separations of the microwave resonator device are determined by the first and second intrinsic resonance frequencies and the coupling between the first and second transmission line resonators.

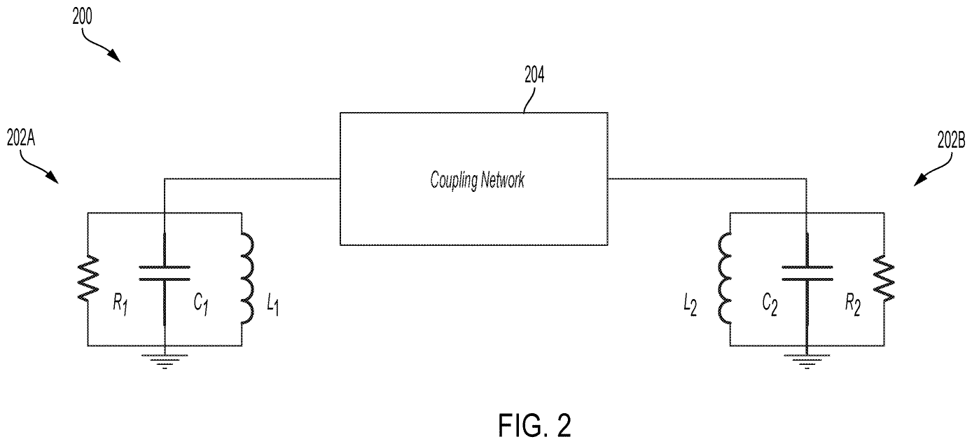

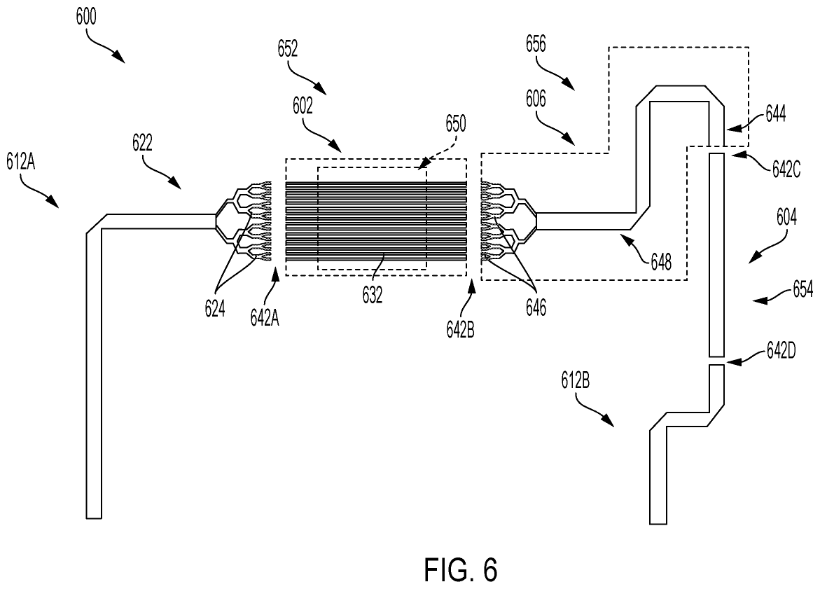

In some instances, the microwave resonator device of the resonator unit 106 may be represented by one or more of the equivalent circuit diagrams shown in FIGS. 2, 3A-3B, 4A-4B, 5A-5B, 10A-10B, and 11A-11B. In some instances, the microwave resonator device of the resonator unit 106 may be implemented as one or more of the resonator device 600, 800, 1200 in FIGS. 6, 8, 12, or in another manner. In some instances, the resonator unit 106 may include signal wirings for communicating microwave signals and digital control signals, cryogenic receiver components, and internal hardware for temperature setting and stabilization. In some instances, the control system 114 (e.g., the computer and signal processing units 102 and the spectrometer 104) may also communicate electron spin resonance control signals to the microwave resonator device of the resonator unit 106 and receive electron spin resonance detection signals from the microwave resonator device of the resonator unit 106.

In some implementations, the TCU 108 monitors and stabilizes the temperature of the environment where the microwave resonator device of the resonator unit 106 resides. In some examples, the example electron spin resonance system 100 includes other circuits or components. For example, the TCU 108 may measure and stabilize temperatures of various components using closed loop feedback control. In some instances, the example electron spin resonance system 100 includes a cryostat cooled by liquid Helium or liquid Nitrogen which can be maintained at a cryogenic environment (e.g., at 77 K, 4 K, or other cryogenic temperatures below 273 K). In certain examples, a cryostat of the example electron spin resonance system 100 includes liquid cryogen-free system, e.g., dry cryostats. In some instances, a cryostat of the example electron spin resonance system 100 includes internal control hardware for temperature setting and stabilization.

In some instances, the FCU 110 can monitor, stabilize, and vary a primary magnetic field in the electron spin resonance system. The primary magnetic field is the external Bo field (the quantizing field) that is applied to the sample region and is generated by the primary magnet system 112, which can be implemented as an electromagnet, a permanent magnet, a superconducting magnet, or another type of magnet. For example, the FCU 110 may measure and stabilize a quantizing magnetic field using closed loop feedback control. The FCU 110 of the electron spin resonance system 100 may include a magnet configured to generate magnetic fields corresponding to X-band spin resonance (e.g., a field strength in the range of approximately 0-4000 G). In some implementations, the FCU 110 further includes a Hall probe which interfaces with the computer and signal processing units 102 to receive control signals from the computer and signal processing units 102 and apply appropriate current to the primary magnet system 112.

In some implementations, the primary magnet system 112 provides a primary magnetic field in the electron spin resonance system 100 including the sample region of the microwave resonator device in the resonator unit 106 (e.g., the sample regions 650, 850, 1250 in FIGS. 6, 8, 12). As shown in FIG. 1, the primary magnet system 112 in the electron spin resonance system 100 generates a primary magnetic field in a controlled environment of a sample region defined by the resonator unit 106. In some implementations, the primary magnet system 112 includes an electromagnet system that can be controlled by the FCU 110 by tuning the current from an electromagnet power supply. In some instances, the primary magnet system 112 may include a gradient system that generates one or more gradient fields that spatially vary over the sample region. Generally, the primary magnetic field generated by the primary magnet system 112 controls electron spins; quantizes the spin states; sets the Larmor frequency of the spin ensemble; interact with nitrogen-vacancy (NV) centers; polarize electron spins in NV centers; and may be used in other applications.

In some aspects of operation, a spin ensemble in the sample interacts with the resonator unit 106. Control of spins in the sample can be achieved, for example, by a radio frequency or microwave magnetic field generated by the resonator unit 106. The drive frequency can be tuned to the spins' resonance frequency, which is determined by the strength of the primary magnetic field and the gyromagnetic ratio of the spins. The spins can be a collection of particles having non-zero spin that interact magnetically with the applied fields. For example, the spin ensemble can include nuclear spins, electron spins, or a combination of nuclear and electron spins. Examples of nuclear spins include hydrogen nuclei (1H), carbon-13 nuclei (13C), and others. In some implementations, the spin ensemble is a collection of identical spin-½ free electron spins attached to an ensemble of large molecules.

FIG. 2 is a circuit diagram showing an equivalent circuit model of an example microwave resonator device 200. As shown in FIG. 2, the example microwave resonator device 200 includes a first single-mode resonator 202A and a second single-mode resonator 202B coupled in series through a coupling network 204. As shown in FIG. 2, each of the two single-mode resonators 202A, 202B includes an RLC resonator with a combination of a resistor (R), an inductor (L), and a capacitor (C) to resonate at a specific frequency (e.g., microwave frequency). In particular, the first single-mode resonator 202A includes a first RLC resonator with a first resistor having a resistance of R₁, a first inductor having an inductance of L₁, and a first capacitor having a capacitance of C₁; and the second single-mode resonator 202B includes a second RLC resonator with a second resistor having a resistance of R₂, a second inductor having an inductance of L₂, and a second capacitor having a capacitance of C₂.

The coupling between the first and second single-mode resonators 202A, 202B through the coupling network 204 can cause a mixing or a hybridization of independent resonator modes to create a multi-mode resonance structure that spans both single-mode resonators 202A, 202B. In this configuration, a sample is physically placed near one of the resonator devices, e.g., the first single-mode resonator 202A, known as the ‘primary resonator,’ to allow exchange of magnetic field energy at two distinct resonance frequencies. The second single-mode resonator 202B, referred to as the ‘auxiliary resonator’, does not directly interact with the sample but instead serves to introduce additional microwave resonant modes in the first single-mode resonator 202A.

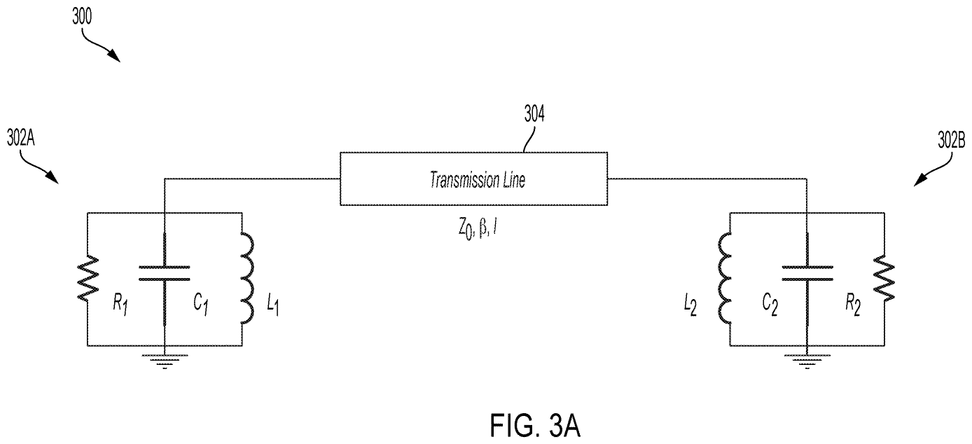

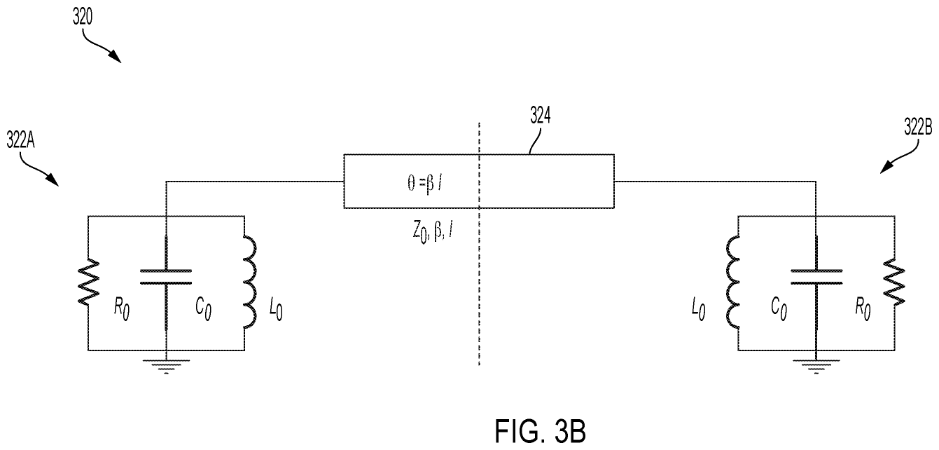

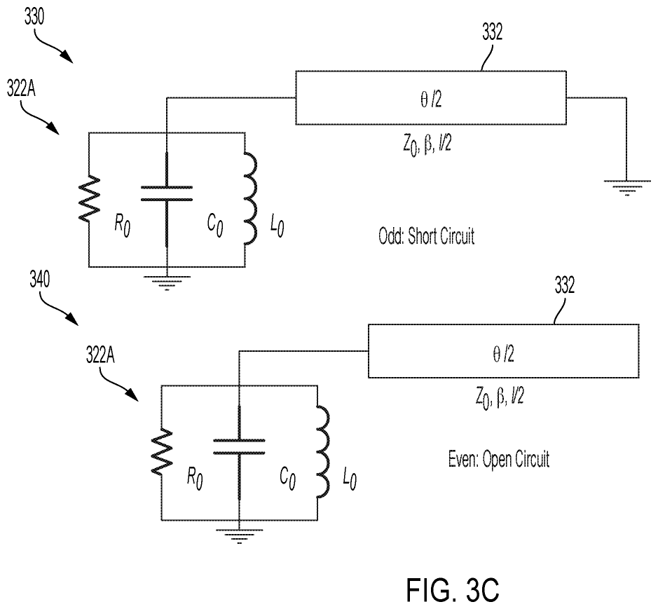

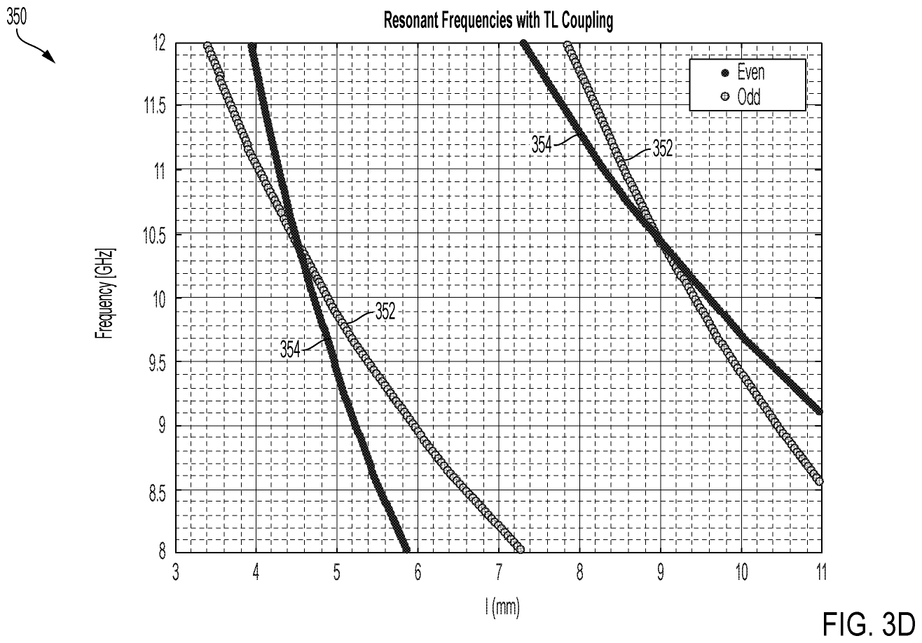

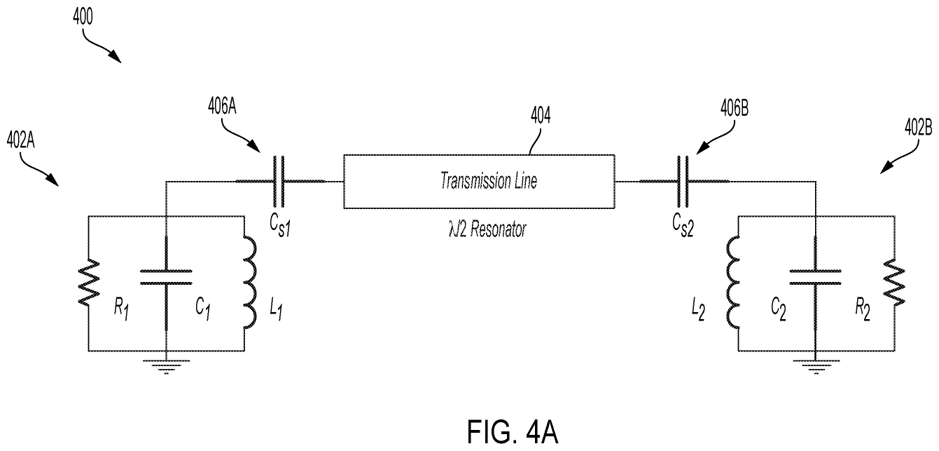

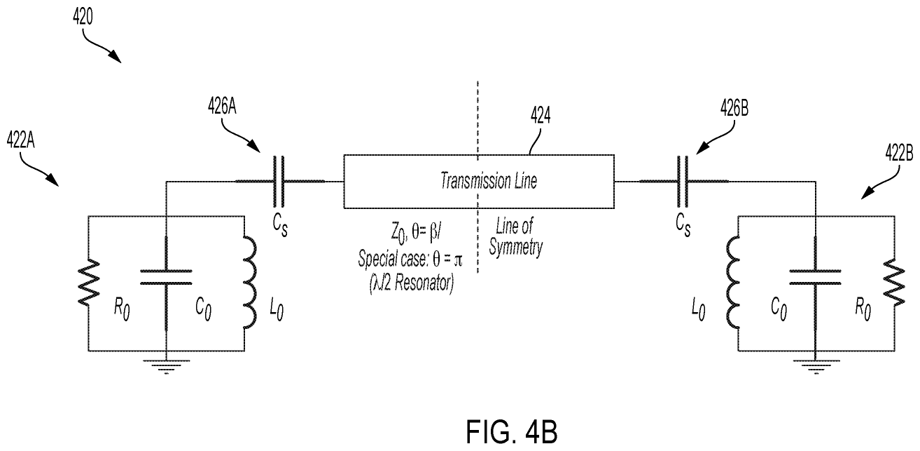

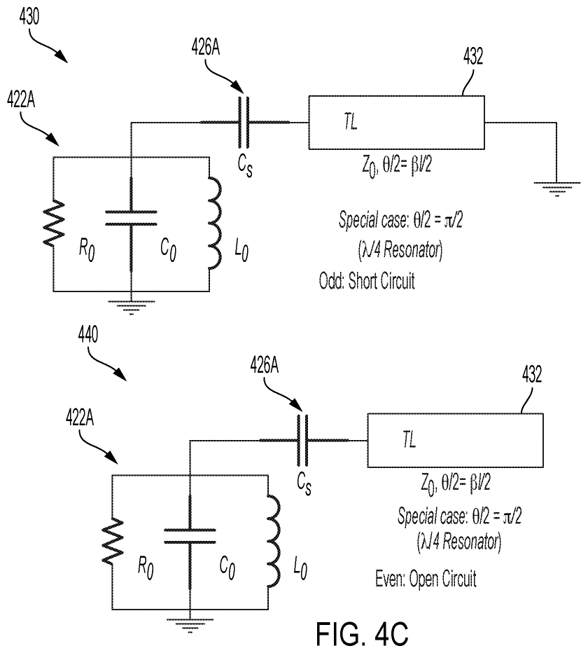

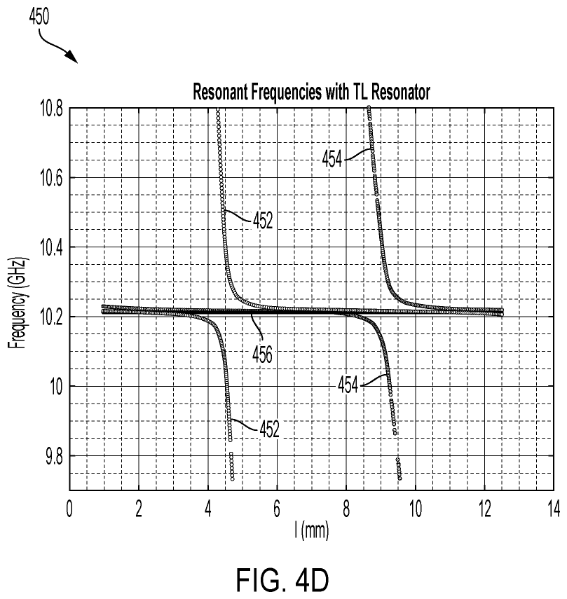

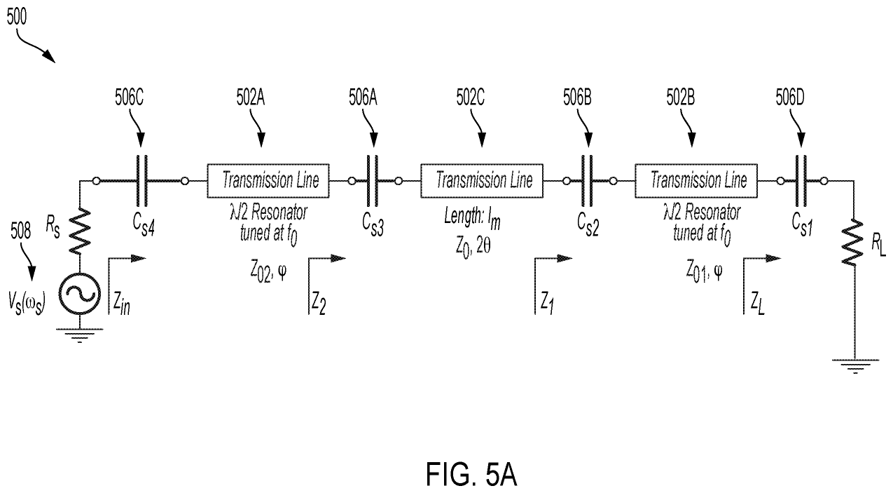

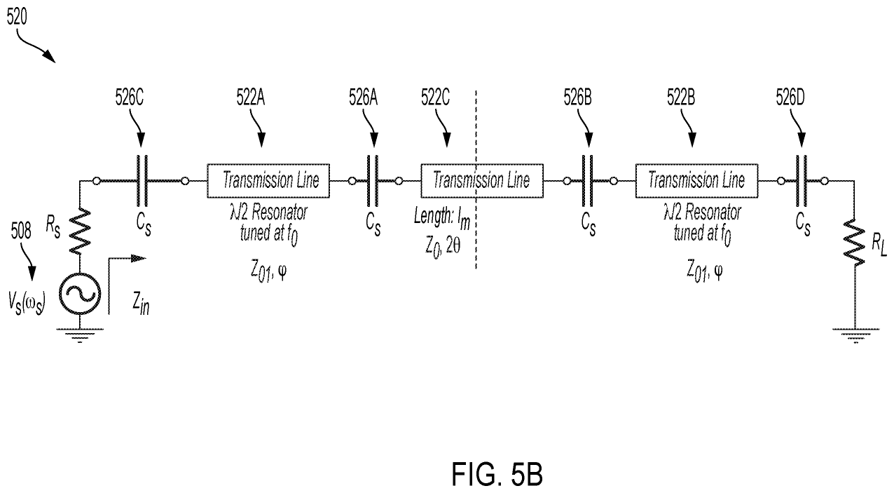

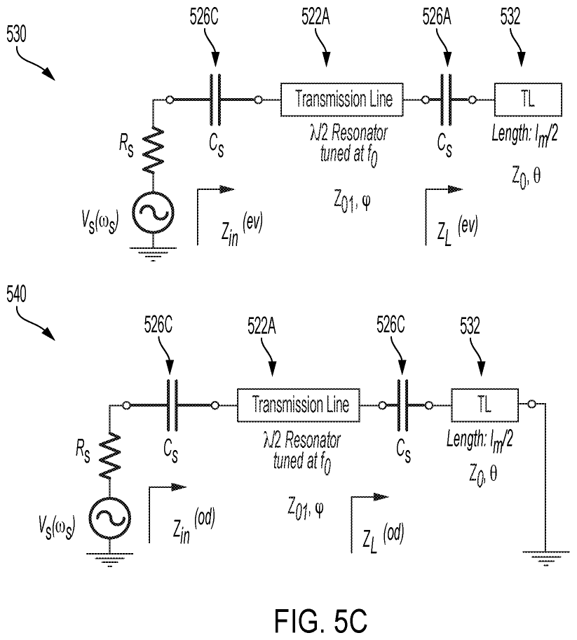

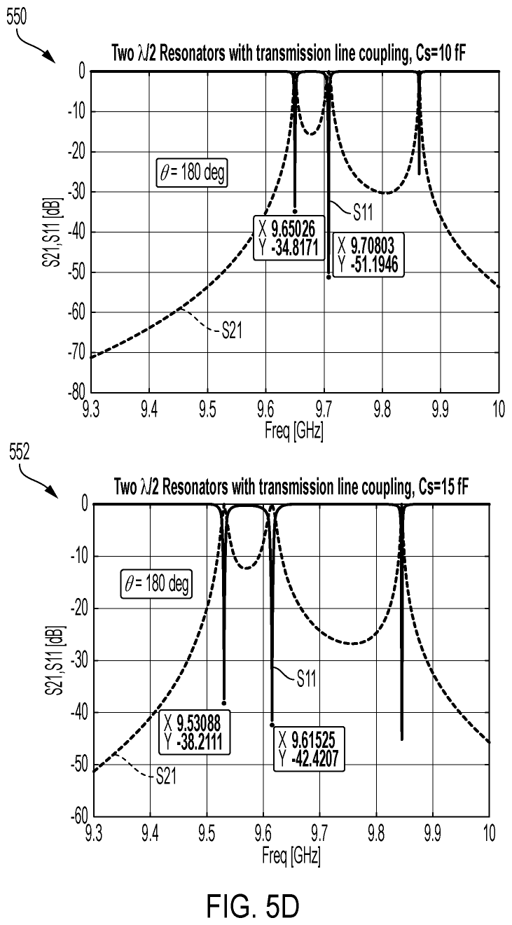

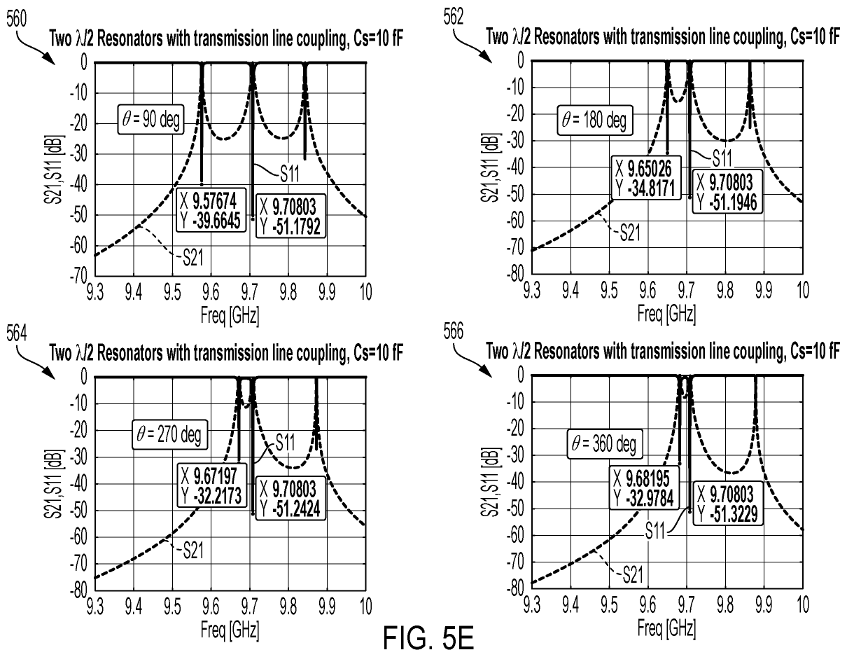

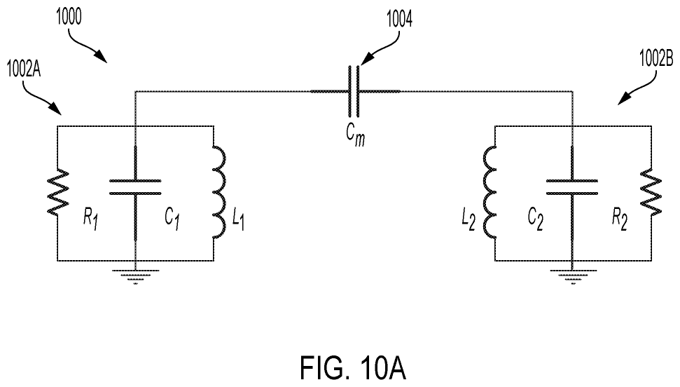

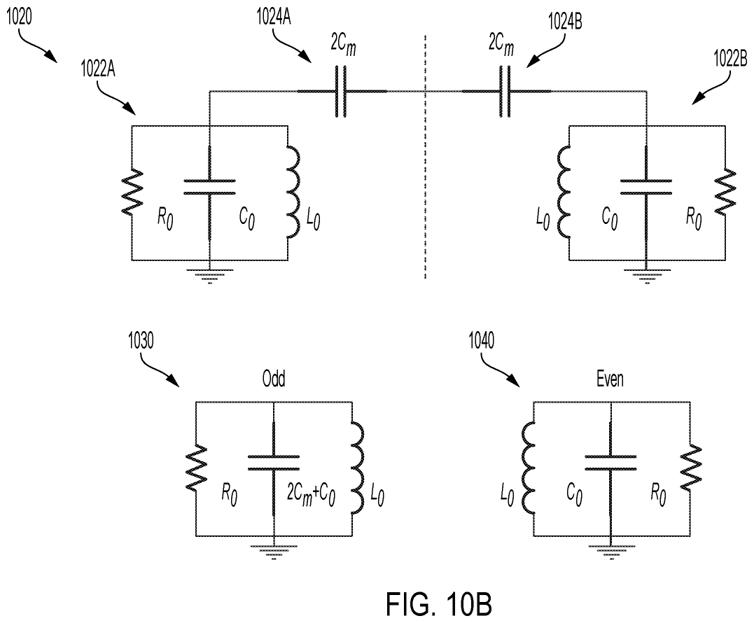

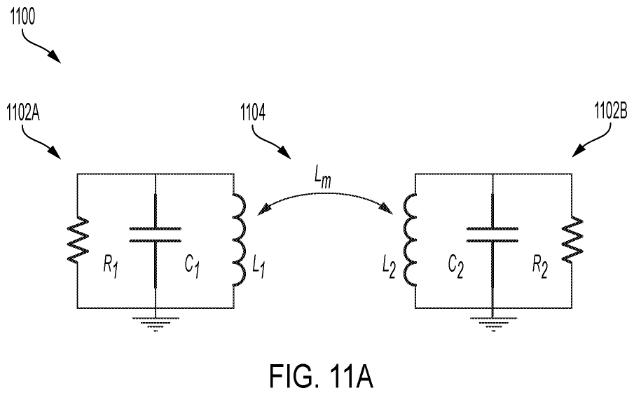

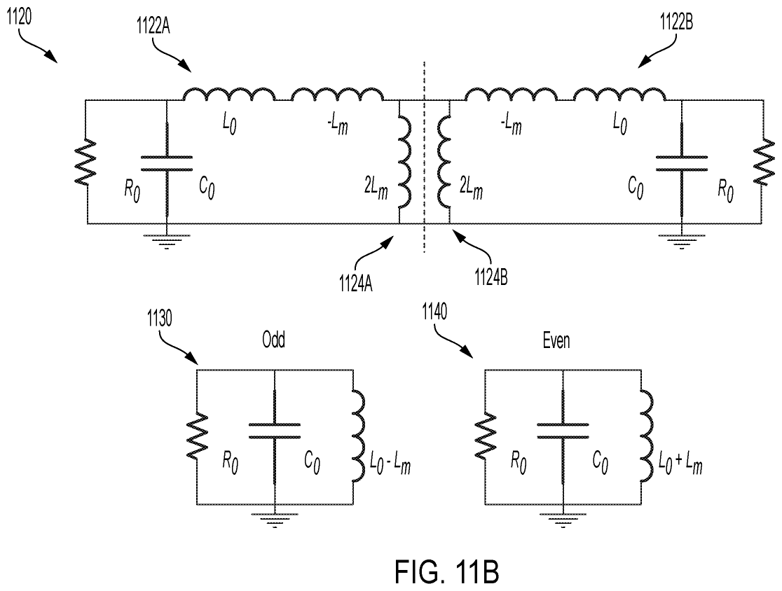

In some instances, the coupling network 204 includes microwave devices and circuit components that are configured to provide coupling between the two single-mode resonators 202A, 202B. A coupling network 204 may be implemented in a variety of different ways. For example, the coupling network 204 may include an impedance/admittance inverter with series/shunt reactive elements (such as capacitors and inductors), self-coupling, mutual coupling, or any combination of these elements in T or n configuration; a transmission line resonator or another resonator; a sophisticated coupled-line broadband phase shifter, such as Schiffman phase shifters; stepped-impedance phase shifters; slow-wave periodic-structures; hybrid-90 structures with reflective loads; or any other general 2-port network. For planar patterned devices, the coupling network 204 may be implemented in either a single layer or multiple layers, including ground planes. In some instances, the coupling network 204 may be implemented as the transmission line 304 324, in FIGS. 3A-3B, the coupling transmission line resonator 404, 424 in FIGS. 4A-4B, the coupling transmission line resonator 502C, 522C, 606, 806 in FIGS. 5A-5B, 6, 8, the coupling capacitor 1004 in FIG. 10A, the coupling inductor 1104 in FIG. 11A, or in another manner.

In some instances, the first and second single-mode resonators 202A, 202B may have distinct intrinsic resonance frequencies, e.g., the first and second single-mode resonators 202A, 202B may be asynchronously tuned. In certain instances, the first and second single-mode resonators 202A, 202B may be synchronously tuned with identical intrinsic resonance frequencies; and a frequency separation of the hybridized resonance modes may be created and tuned by tuning design parameters of the coupling network 204. In some instances, the frequency separation may be in a range of 30-100 MHz or another range for applications such as double-resonance electron spin resonance.

FIG. 3A is a circuit diagram showing an equivalent circuit model of an example microwave resonator device 300. As shown in FIG. 3A, the example microwave resonator device 300 includes a first single-mode resonator 302A and a second single-mode resonator 302B, which are coupled in series through a coupling network implemented as a transmission line 304. As shown in FIG. 3A, each of the two single-mode resonators 302A, 302B includes an RLC resonator with a combination of a resistor (R), an inductor (L), and a capacitor (C) to resonate a specific frequency. In particular, the first single-mode resonator 302A includes a first RLC resonator with a first resistor having a resistance of R₁, a first inductor having an inductance of L₁, and a first capacitor having a capacitance of C₁; and the second single-mode resonator 302B includes a second RLC resonator with a second resistor having a resistance of R₂, a second inductor having an inductance of L₂, and a second capacitor having a capacitance of C₂. In some instances, the first and second single-mode resonators 302A, 302B may be implemented and operated as the first and second single-mode resonators 202A, 202B in FIG. 2.

The fundamental design principles can be understood through analysis of two RLC resonators connected in series through a transmission line (TL). The first and second single-mode resonators 302A, 302B are taken to be positioned at a sufficient distance to ensure no overlap between their fields: \vec{E}₁·\vec{E}₂=0, and \vec{H}₁·\vec{H}₂=0, where E and H represent the electric and magnetic field vectors of the first single-mode resonator 302A and the second single-mode resonator 302B, respectively. Thus, coupling between the first and second single-mode resonators 302A, 302B occurs only through the transmission line 304.

In some implementations, the transmission line 304 can be characterized by a length l, a frequency dependent phase propagation constant 8, and a characteristic impedance Z₀. The electrical length of the transmission line 304 at frequency ω is θ=βl=ωl/vₚ, where vₚ is the phase velocity of the transmission line 304. The values of the inductors (L₁ and L₂), capacitors (C₁ and C₂), and resistors (R₁ and R₂) specify the intrinsic resonance frequencies of each of the first and second single-mode resonators 302A, 302B when uncoupled.

The intrinsic resonance frequencies of the first and second single-mode resonators 302A, 302B can generally have different values, given by ω₀₁=1/\sqrt{L₁C₁} and ω₀₂=1\sqrt{L₂C₂}. In this case, when uncoupled, the first and second single-mode resonators 302A, 302B have two distinct microwave resonant modes, which are spatially disjoint. The coupling introduced by the transmission line 304 hybridizes the two resonant modes of the first and second single-mode resonators 302A, 302B to enable multiple resonant modes that are spatially dispersed over both resonators 302A, 302B.

FIG. 3B is a circuit diagram showing an equivalent circuit model of an example symmetric microwave resonator device 320. As shown in FIG. 3B, the example microwave resonator device 320 includes a first single-mode resonator 322A and a second single-mode resonator 322B, which are coupled in series through a transmission line 324. Each of the two single-mode resonators 322A, 322B includes an RLC resonator with a combination of a resistor (R), an inductor (L), and a capacitor (C) to resonate at a specific microwave frequency. In particular, the first single-mode resonator 322A and the second single-mode resonator 322B are identical, each including an RLC resonator with a resistor having a resistance of R₀, an inductor having an inductance of L₀, and a capacitor having a capacitance of C₀. In some instances, the first and second single-mode resonators 322A, 322B may be implemented and operated as the first and second single-mode resonators 202A, 202B in FIG. 2.

In some implementations, the first and second single-mode resonators 322A, 322B in FIG. 3B are synchronously tuned to resonate at the same resonance frequency. The circuit exhibits symmetry that permits an “Even” and “Odd” mode analysis based on the superposition theorem as shown in FIG. 3C. The Odd mode represented by an effective circuit 330 in FIG. 3C corresponds to a transmission line 332 (e.g., half of the transmission line 324 in FIG. 3B) being terminated with a short circuit and behaving as an inductor within the frequency range of interest. Conversely, the Even mode represented by an effective circuit 340 in FIG. 3C corresponds to the transmission line 332 being terminated with an open circuit and behaving as a capacitor within the frequency range of interest. The transmission line 332 is characterized by a length l/2, a frequency dependent phase propagation constant B, and a characteristic impedance Z₀. The electrical length of the transmission line 304 at frequency ω is θ/2.

In the case of a microwave resonator device 320 with two synchronously tuned identical single-mode resonators 322A, 322B coupled by the transmission line 324 as shown in FIG. 3B, the resonance frequencies of the microwave resonator device 320 can be explicitly determined using the following equations, where l, Vₚ, and Z₀ represent the length, phase velocity, and characteristic impedance of the transmission line 324, respectively:

$$Even mode : \frac{{ω}^{2} {L}_{0} {C}_{0} - 1}{ω {L}_{0}} + \frac{tan ( \frac{ω l}{2 {V}_{p}} )}{{Z}_{0}} = 0 \qquad ( 1 )$$

$$Odd Mode : \frac{{ω}^{2} {L}_{0} {C}_{0} - 1}{ω {L}_{0}} - \frac{cot ( \frac{ω l}{2 {V}_{p}} )}{{Z}_{0}} = 0 \qquad ( 2 )$$

Each equation has a unique solution that depends on the transmission line length l, which can be varied to tune the separation of the two resonance frequencies to a target value.

FIG. 3D is a plot 350 showing resonance frequencies in GHz as a function of the transmission line length I in mm of the transmission line 324 in the microwave resonator device 320 represented by the equivalent circuit diagram shown in FIG. 3B. Circuit parameters in the calculations are Z₀=50 Q, C₀=0.231 pF, L₀=1.015 nH, and Vₚ=9.4e7 m/s. Curves 352 represent the odd mode; and curves 354 represent the even mode.

FIG. 4A is a circuit diagram showing an equivalent circuit model of an example microwave resonator device 400. As shown in FIG. 4A, the example microwave resonator device 400 includes a first single-mode resonator 402A and a second single-mode resonator 402B, which are coupled in series through a transmission line 404.

The first and second single-mode resonators 402A, 402B are capacitively coupled to the transmission line 404 through respective coupling capacitors 406A, 406B. In some instances, the capacitance of the coupling capacitors 406A, 406B can be different; and are given by the circuit parameters Cₛ₁ and Cₛ₂. In some instances, the transmission line 404 acts as a distributed λ/2 coupling resonator. In this case, the first and second single-mode resonators 402A, 402B are coupled through this intermediary coupling resonator.

As shown in FIG. 4A, each of the two single-mode resonators 402A, 402B includes an RLC resonator with a combination of a resistor (R), an inductor (L), and a capacitor (C) to resonate a specific frequency. In particular, the first single-mode resonator 402A includes a first RLC resonator with a first resistor having a resistance of R₁, a first inductor having an inductance of L₁, and a first capacitor having a capacitance of C₁; and the second single-mode resonator 402B includes a second RLC resonator with a second resistor having a resistance of R₂, a second inductor having an inductance of L₂, and a second capacitor having a capacitance of C₂. In some instances, the first and second single-mode resonators 402A, 402B may be implemented and operated as the first and second single-mode resonators 202A, 202B in FIG. 2.

In some implementations, the transmission line 404 is characterized by a length l, a frequency dependent phase propagation constant B, and a characteristic impedance Z₀. The electrical length of the transmission line 404 at a frequency ω is θ=βl=ωl/vₚ, where vₚ is the phase velocity of transmission line 404. The values of the inductors (L₁ and L₂), capacitors (C₁ and C₂), and resistors (R₁ and R₂) specify the intrinsic resonance frequencies of each of the first and second single-mode resonators 402A, 402B when uncoupled.

FIG. 4B is a circuit diagram showing an equivalent circuit model of an example symmetric microwave resonator device 420. As shown in FIG. 4B, the example microwave resonator device 420 includes a first single-mode resonator 422A and a second single-mode resonator 422B coupled in series through a transmission line 424. The first and second single-mode resonators 422A, 422B are coupled to the transmission line 424 through respective coupling capacitors 426A, 426B. As shown in FIG. 4B, each of the two single-mode resonators 422A, 422B includes an RLC resonator with a combination of a resistor (R), an inductor (L), and a capacitor (C) to resonate a specific microwave frequency. In particular, the first single-mode resonator 422A and the second single-mode resonator 422B are identical, each including an RLC resonator with a resistor having a resistance of R₀, an inductor having an inductance of L₀, and a capacitor having a capacitance of C₀. In some instances, the first and second single-mode resonators 422A, 422B may be implemented and operated as the first and second single-mode resonators 322A, 322B in FIG. 3B.

In some implementations, the first and second single-mode resonators 422A, 422B in FIG. 4B are synchronously tuned to resonate at the same resonance frequency. The circuit exhibits symmetry that permits an “Even” and “Odd” mode analysis based on the superposition theorem as shown in FIG. 4C. The odd mode represented by an effective circuit 430 in FIG. 4C corresponds to a transmission line 432 (e.g., half of the transmission line 424 in FIG. 4B) being terminated with a short circuit and behaving as an inductor within the frequency range of interest. Conversely, the Even mode represented by an effective circuit 440 in FIG. 4C corresponds to the transmission line 432 being terminated with an open circuit and behaving as a capacitor within the frequency range of interest. The transmission line 432 is characterized by a length l/2, a frequency dependent phase propagation constant β, and a characteristic impedance Z₀. The electrical length of the transmission line 432 at frequency ω is θ/2. When the electrical length θ/2=π/2, the transmission line 432 is a λ/4 transmission line resonator.

In the case of a microwave resonator device 420 with two synchronously tuned identical single-mode resonator devices 422A, 422B as shown in FIG. 4B, the resonance frequencies of the microwave resonator device 420 can be explicitly determined using the following equations, where l, Vₚ, and Z₀ represent the length, phase velocity, and characteristic impedance of the transmission line 424, respectively:

$$Even mode : \frac{{ω}^{2} {L}_{0} {C}_{0} - 1}{ω {L}_{0}} + \frac{ω {C}_{s}}{1 + {Z}_{0} ω {C}_{s} cot ( \frac{ω l}{2 {V}_{p}} )} = 0 \qquad ( 3 )$$

$$Odd Mode : \frac{{ω}^{2} {L}_{0} {C}_{0} - 1}{ω {L}_{0}} + \frac{ω {C}_{s}}{1 - {Z}_{0} ω {C}_{s} tan ( \frac{ω l}{2 {V}_{p}} )} = 0 \qquad ( 4 )$$

In contrast to the microwave resonator device 320 where two single-mode resonators 322A, 322B are coupled through an ideal transmission line 324 shown in FIG. 3B, treatment of the transmission line 424 as a coupling resonator exhibits three distinct microwave resonant modes instead of two. For the case of 0<θ/2<π/2, the short-terminated transmission line 432 represented by the effective circuit 430 in the Odd mode as shown in FIG. 4C has a positive inductive impedance of jZ₀ tan (θ/2), leading to two solutions of equation (3), corresponding to two distinct microwave resonant modes. The open-terminated transmission line 432 represented by the circuit diagram 440 in the Even mode as shown in FIG. 4D has a negative capacitive impedance of −jZ₀ cot(θ/2), with a single solution to equation (4). Thus, for 0<θ/2<π/2 there are three distinct resonance frequencies of the microwave resonator device 420 in FIG. 4B: two for the Odd mode and one for the Even mode. In some instances, a similar behavior may be obtained when the electrical length of the transmission line 432 is in a range of π/2<θ/2<π.

FIG. 4D is a plot 450 showing resonance frequencies in GHz as a function of the transmission line length I in mm of the transmission line 424 in the microwave resonator device 420 represented by the equivalent circuit diagram shown in FIG. 4B. Circuit parameters in the calculations are Z₀=50 Q, C₀=0.231 pF, Cₛ=8.4 fF, L₀=1.015 nH, and Vₚ=9.4e7 m/s. Curves 452 represent the first resonance; curves 454 represent the second resonance; and curves 456 represent the third resonance. As shown in FIG. 4D, the transmission line length I of the transmission line 424 can be varied to tune the separation of the three resonance frequencies to target values. Depending on the application, any two distinct resonance frequencies may be used for double-resonance electron spin resonance measurements, or all three may be used for triple-resonance electron spin resonance measurements.

FIG. 5A is a circuit diagram showing an equivalent circuit model of an example microwave resonator device 500. As shown in FIG. 5A, the example microwave resonator device 500 includes a first transmission line resonator 502A and a second transmission line resonator 502B, which are coupled in series through a third transmission line resonator 502C. A first end of the first transmission line resonator 502A is capacitively coupled to a first end of the third transmission line resonator 502C through a first coupling capacitor 506A; and a first end of the second transmission line resonator 502B is capacitively coupled to a second end of the third transmission line resonator 502C through a second coupling capacitor 506B. In some instances, the capacitances of the first and second coupling capacitors 506A, 506B can be different, e.g., Cₛ₃≠Cₛ₂. Further, a second end of the first transmission line resonator 502A is capacitively coupled to a voltage source 508 through a third coupling capacitor 506C; and a second end of the second transmission line resonator 502B is capacitively coupled to the ground through a fourth coupling capacitor 506D. In some implementations, each of the first and second transmission line resonators 502A, 502B are implemented as a λ/2 transmission line resonator; and are identical, e.g., are synchronously tuned to resonate at the same intrinsic resonance frequency f₀. The first and second transmission line resonators 502A, 502B are characterized by a characteristic impedance Z₀₁, Z₀₂. The electrical lengths of the first and second transmission line resonators 502A, 502B at frequency ω is o. The third transmission line resonator 502C is characterized by a length lₘ, a characteristic impedance Z, and an electrical length of 2θ. In some instances, the third transmission line resonator 502C may be also a λ/2 transmission line resonator. In some instances, a control signal provided by the voltage source is received at the first transmission line resonator 502A.

The characteristic impedance of each transmission line resonator and their respective coupling capacitors are considered independent for the sake of generality. The first, second, and third transmission line resonators 502A, 502B, 502C may be implemented as a single microstrip line resonator, a multiple microstrip line resonator, a coplanar waveguide resonator, or another type of planar transmission line resonator. In some instances, the transmission line resonator device 500 includes multiple conductors made of superconducting or normal metal material.

In this example, the frequency of interest is ω₀=2π×9.6 GHz and the electrical lengths of interest are φ₀=180° for the first and second transmission line resonators 502A, 502B, and 20, for the third transmission line resonator 502C. The electrical lengths of the first and second transmission line resonators 502A, 502B are configured as identical and set as constant, e.g.,

$$φ = ω \frac{{φ}_{0}}{{ω}_{0}} ,$$

while the electrical length of the third transmission line resonator 502C, e.g.,

$$2 θ = ω \frac{2 {θ}_{0}}{{ω}_{0}} ,$$

can be varied, modified and otherwise controlled to tune the frequency location of the three hybridized microwave resonant modes (e.g., resonance frequencies of the microwave resonator device 500) and frequency separations among the three microwave resonant modes.

The behavior of the equivalent circuit model of the example microwave resonator device 500 shown in FIG. 5A is fully specified by the impedances shown in FIG.

$${Z}_{L} = \frac{- j + ω {C}_{s 1} {R}_{L}}{ω {C}_{s 1}} \qquad ( 5 )$$

$${Z}_{1} = - j \frac{1}{ω {C}_{s 2}} + {Z}_{01} \frac{{Z}_{L} + j {Z}_{01} tan φ}{{Z}_{01} + j {Z}_{L} tan φ} \qquad ( 6 )$$

$${Z}_{2} = - j \frac{1}{ω {C}_{s 3}} + {Z}_{0} \frac{{Z}_{1} + j {Z}_{0} tan 2 θ}{{Z}_{0} + j {Z}_{1} tan 2 θ} \qquad ( 7 )$$

$${Z}_{in} = - j \frac{1}{ω {C}_{s 4}} + {Z}_{02} \frac{{Z}_{2} + j {Z}_{02} tan φ}{{Z}_{02} + j {Z}_{2} tan φ} \qquad ( 8 )$$

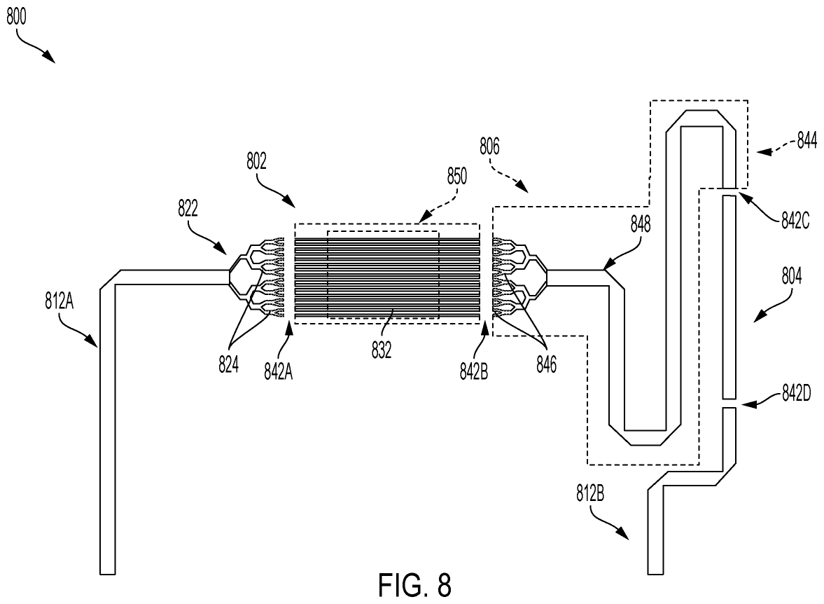

In some implementations, the first, second, and third transmission line resonators 502A, 502B, 502C each may be implemented as a planar transmission line resonator, such as a stripline, a microstrip line, a coplanar waveguide, a suspended stripline, or another type of transmission line. For example, the first, second, and third transmission line resonators 502A, 502B, 502C each may include a single microstrip resonator or an array of multiple microstrip resonators. In some instances, the first, second, and third transmission line resonators 502A, 502B, 502C may be the same type of planar transmission line resonator or different type of planar transmission line resonators. In some instances, when the first transmission line resonator 502A includes multiple microstrip line resonators and the second transmission line resonator 502B includes a single microstrip line resonator, the third transmission line resonators 502C may have a branching structure configured to effectively couple the multiple microstrip line resonators with the single microstrip line resonator. In some instances, the first, second, and third transmission line resonators 502A, 502B, 502C may be implemented as the primary, auxiliary, and coupling transmission line resonators 602, 604, 606 shown in FIG. 6, as the primary, auxiliary, and coupling transmission line resonators 802, 804, 806 shown in FIG. 8, or in another manner.

FIG. 5B is a circuit diagram showing an equivalent circuit model of an example symmetric microwave resonator device 520. As shown in FIG. 5B, the example microwave resonator device 520 includes a first transmission line resonator 522A and a second transmission line resonator 522B coupled in series through a third transmission line resonator 522C. A first end of the first transmission line resonator 522A is capacitively coupled to a first end of the third transmission line resonator 522C through a first coupling capacitor 526A; and a first end of the second transmission line resonator 522B is capacitively coupled to a second end of the third transmission line resonator 522C through a second coupling capacitor 526B. Further, a second end of the first transmission line resonator 522A is capacitively coupled to a voltage source 508 through a third coupling capacitor 526C; and a second end of the second transmission line resonator 522B is capacitively coupled to the ground through a fourth coupling capacitor 526D. In some instances, capacitance values of the coupling capacitors 526A, 526B, 526C, 526D are identical and can be characterized as Cₛ.

In some implementations, the first and second transmission line resonators 522A, 522B in FIG. 5B are synchronously tuned to resonate at the same resonance frequency fo. The circuit exhibits symmetry that permits an “Even” and “Odd” mode analysis based on the superposition theorem as shown in FIG. 5C. The Odd mode represented by an effective circuit 530 in FIG. 5C corresponds to a transmission line resonator 532 (e.g., half of the third transmission line resonator 522C in FIG. 5B) being terminated with a short circuit and behaving as an inductor within the frequency range of interest. Conversely, the even mode represented by an effective circuit 540 in FIG. 5C corresponds to the transmission line resonator 532 being terminated with an open circuit and behaving as a capacitor within the frequency range of interest. The transmission line resonator 532 is characterized by a length lₘ/2, a characteristic impedance Z₀, and an electrical length of θ. In some instances, the resonance frequencies of the first and second transmission line resonators 522A, 522B may have a resonance detuning.

Given the symmetry of the circuit diagram shown in FIG. 5B, Even/Odd mode analysis may be used to simplify the calculations of the impedances shown in FIG. 5C, given by,

$${Z}_{L}^{( e v )} = \frac{- j}{ω {C}_{s}} - j {Z}_{0} cot θ \qquad ( 9 )$$

$${Z}_{L}^{( od )} = \frac{- j}{ω {C}_{s}} + j {Z}_{0} tan θ \qquad ( 10 )$$

$${Z}_{i n}^{( e v )} = \frac{- j}{ω {C}_{s}} + {Z}_{01} \frac{{Z}_{L}^{( e v )} + j {Z}_{01} tan φ}{{Z}_{01} + j {Z}_{L}^{( e v )} tan φ} \qquad ( 11 )$$

$${Z}_{i n}^{( od )} = \frac{- j}{ω {C}_{s}} + {Z}_{01} \frac{{Z}_{L}^{( od )} + j {Z}_{01} tan φ}{{Z}_{01} + j {Z}_{L}^{( od )} tan φ} \qquad ( 12 )$$

$${Z}_{i n} = {R}_{s} + \frac{2 ( {Z}_{i n}^{( e v )} {Z}_{i n}^{( od )} - {R}_{s}^{2} )}{2 {R}_{s} + {Z}_{i n}^{( e v )} + {Z}_{i n}^{( od )}} \qquad ( 13 )$$

FIG. 5D includes plots 550, 552 showing S-parameters (S11, S21) in dB as a function of frequency in GHz at different coupling capacitance values Cₛ of the microwave resonator device 520 represented by the equivalent circuit model shown in FIG. 5B. As shown in FIG. 5D, by changing the capacitance values Cₛ of the coupling capacitors 526A, 526B, 526C, 526D, the three resonant modes and the frequency separations among microwave resonant modes can be tuned. The electrical length θ of the third transmission line resonator 502C was kept at a constant value of 180 degrees; and the first and second transmission line resonators 502A, 502B are implemented as a λ/2 transmission line resonator. As shown in FIG. 5D, when the capacitance value Cₛ is varied from 10 fF to 15 fF, all three microwave resonance modes are shifted; and the resonance frequencies of the microwave resonator device 520 are shifted to lower values. As further shown in the plot 550, when the coupling capacitance value Cₛ of 10 fF was used, the frequency separation Δf between the first two resonance frequencies at 9.65026 GHz and 9.70803 GHz is 57 MHz. As shown in the plot 560, when the coupling capacitance value Cₛ of 15 fF is used, the frequency separation Δf between the first two resonance frequencies at 9.53088 GHz and 9.61525 GHz is 84 MHz. In this example, when the capacitance values Cₛ is varied from 10 fF to 15 fF, the frequency separation between the two microwave resonant modes is increased.

FIG. 5E includes plots 560, 562, 564, 566 showing S-parameters (S11, S21) in dB as a function of frequency in GHz at a constant capacitance value Cₛ of 10 fF with the third transmission line resonator 522C at different electrical lengths θ in the microwave resonator device 520 represented by the equivalent circuit diagram shown in FIG. 5B. As shown in FIG. 5E, by changing the electrical length θ of the third transmission line resonator 522C, the frequency separation between the three microwave resonant modes can be tuned to desired values. As shown in the plot 560, when the electrical length θ of the third transmission line 522C is 90 degrees, the frequency separation Δf between the first two resonance frequencies at 9.57674 GHz and 9.70803 GHz is 131 MHz. As shown in the plot 562, when the electrical length θ of the third transmission line 522C is 180 degrees, the frequency separation Δf between the first two resonance frequencies at 9.65026 GHz and 9.70803 GHz is 58 MHz. As shown in the plot 564, when the electrical length θ of the third transmission line 522C is 270 degrees, the frequency separation Δf between the first two resonance frequencies at 9.67197 GHz and 9.70803 GHz is 36 MHz. As shown in the plot 566, when the electrical length θ of the third transmission line 522C is 360 degrees, the frequency separation Δf between the first two resonance frequencies at 9.68195 GHZ and 9.70803 GHz is 26 MHz. In this example, increasing the electrical length θ of the third transmission line 522C, the first and third microwave resonant modes are shifted to high values effectively reducing the frequency separation between the first and second microwave resonant modes. As shown in FIG. 5E, the second microwave resonant mode was not affected and maintained at the same resonance frequency of 9.70803 GHz.

FIG. 6 is a schematic diagram showing aspects of an example microwave resonator device 600. As shown in FIG. 6, the microwave resonator device 600 includes a primary transmission line resonator 602 and an auxiliary transmission line resonator 604 which are coupled by a coupling transmission line resonator 606. In some implementations, the microwave resonator device 600 includes multiple conductors and a ground plane on a substrate, which are configured to collectively support multiple microwave resonant modes. The primary transmission line resonator 602 includes a first subset of conductors configured in an array of conductive segments; and the auxiliary transmission line resonator 604 includes a second subset of conductors; and the coupling transmission line resonator 606 includes a third subset of conductors. The coupling transmission line resonator 606 may have an electrical length θ of 360 degrees or another value. The example microwave resonator device 600 shown in FIG. 6 includes a first terminal 612A and a second terminal 612B. The first and second terminals 612A, 612B, the primary transmission line resonator 602, the auxiliary transmission line resonator 604, the coupling transmission line resonator 606, and the ground plane can define planar transmission line structures on a substrate. The primary, auxiliary, and coupling transmission line resonators 602, 604, 606 are disposed on different areas of a surface of the substrate. The primary transmission line resonator 602 resides on a first area 652 of the substrate; the auxiliary transmission line resonator 604 resides on a second area 654 of the substrate, which is offset from the first area 652; and the coupling transmission line resonator 606 resides on a third area 656 of the substrate, which is offset from the first and second areas 652, 654. The coupling transmission line resonator 606 resides on the surface of a substrate adjacent to the primary and auxiliary transmission line resonator 602, 604. In some instances, the primary, auxiliary, and coupling transmission line resonators 602, 604, 606 may be disposed on opposite surfaces of the substrate. The example microwave resonator device 600 can include additional or different features, and the features of the example microwave resonator device 600 may be arranged in the configuration shown or in another configuration.

In some implementations, the microwave resonator device 600 may be part of the resonator unit 106 of the example electron spin resonance system 100; and coupled with the control system 114 of the electron spin resonance system 100 for providing electron spin resonance control signals to the microwave resonator device 600 to perform multiple resonance measurements of multiple electron spin centers in a sample region 650 of the microwave resonator device 600. In some instances, the control system 114 may operate the microwave resonator device 600 to perform double resonance measurements of the electron spins in the sample region. For example, the microwave resonator device 600 may be operated to perform Double Electron-Electron Resonance (DEER) spectroscopy; Pulse Electron Double Resonance (PELDOR) spectroscopy, or other resonance spectroscopy. The microwave resonator device 600 may be operated to produce a probe frequency that creates observable coherence that evolves under pairwise coupling of the electron spins; and a pump frequency that refocuses pairwise interactions at varying times to reveal a distribution of coupling strength of the pairwise couplings.

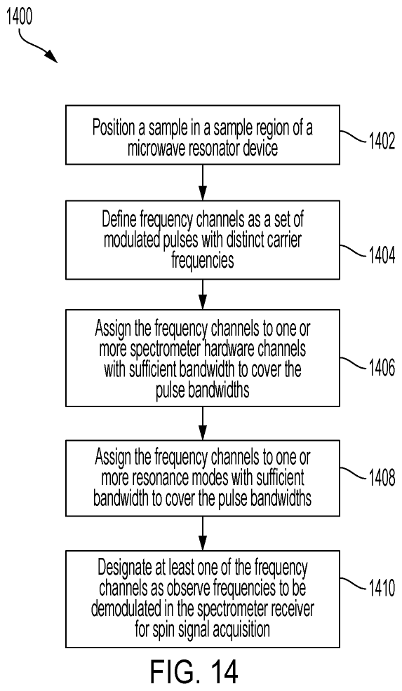

In some implementations, the example microwave resonator device 600 can be operated according to the operations in the example process 1400 in FIG. 14 to produce a time-varying magnetic field in the sample region 650 of the microwave resonator device 600. For example, the microwave resonator device 600 may produce a magnetic field at a radio frequency or microwave frequency configured to manipulate electron spins in the sample region above the primary transmission line resonator 602.

As shown in FIG. 6, each terminal 612A, 612B includes a respective conductor disposed on the substrate. The first terminal 612A has a body 622 and terminal segments 624. The terminal segments 624 extend from the body 622 toward the primary resonator 602. The first terminal 612A includes sixteen terminal segments 624, each extending toward a respective conductive segment 632 of the primary transmission line resonator 602. In some instances, the first terminal 612A can include two terminal segments 624, four terminal segments 624, eight terminal segments 624, sixteen terminal segments 624, thirty-two terminal segments 624, sixty-four terminal segments 624, or in general powers of two, according to the number of the conductive segments 632 in the primary transmission resonator 602. In some implementations, the terminal segments 624 of the first terminal 612A have a width identical to the width of the conductive segments 632 of the primary transmission line resonator 602.

In some implementations, the body 622 of the first terminal 612A includes a branching structure connecting the terminal segments 624. The branching structure can function as a power divider that divides and delivers the power from an input to the terminal segments 624. In some instances, the branching structure can include successive levels (or division stages). In some instances, the branching structure can be configured to achieve desirable branch impedances at each division stage. For example, the branching structure can be designed to match all input impedances of the branches in certain division stages to improve (e.g., increase, maximize, optimize, or otherwise improve) power transfer and reduce signal reflections. In some implementations, the individual branches in each level may have twice the impedance of the individual branches in the preceding level. In some implementations, the power dividers can include tapered branch sections, for example, to adjust the lines for impedance matching.

As shown schematically in FIG. 6, each of the conductive segments 632 in the primary transmission line resonator 602 includes a respective conductor disposed on a surface of the substrate. A first end of each of the conductive segments 632 in the primary transmission line resonator 602 is aligned with a respective terminal segment 624 of the first terminal 612A. Each of the conductive segments 632 is elongated. Each of the conductive segments 632 is capacitively coupled to a respective one of the terminal segments 624, while a second, opposite end of each of the conductive segments 632 is capacitively coupled to a respective one of coupling segments 646 on one end of the coupling transmission line resonator 606. In certain instances, the array of conductive segments 632 can include two conductive segments, four conductive segments, eight conductive segments, sixteen conductive segments, thirty-two conductive segments, sixty-four conductive segments, or in general powers of two.

In some implementations, each of the conductive segments 632 and the ground plane define a microstrip line resonator. In some implementations, the conductive segments 632 in the primary transmission line resonator 602 can be identical to each other. In some examples, the conductive segments 632 are parallel to each other, with equal spacing between each neighboring pair of the conductive segments 632. Here, “parallel” is used broadly to describe structures that are exactly or substantially parallel, when considered on the structures' largest length scales. Two structures can be considered parallel, for example, when their neighboring sides, centerlines, or other dominant structural features are parallel or include only insubstantial deviations from parallel.

The example conductive segment 632 can be sized based on the wavelength of a desired resonance frequency. For example, the length of the conductive segment 632 (e.g., from the first end to the second opposite end) can be designed to produce a first resonant mode around the desired resonance frequency of operation (e.g., ωᵣ=2π·10 GHz). Each conductive segment 632 can be a half-wave resonator, a full-wave resonator, or a multi-half-wave resonator. For example, if the desired resonance frequency is A, the conductive segment 632 can have a length of λ/2, λ, 3λ/2, 2λ, etc.

The multiple conductive segments 632 can be configured to resonate at the same microwave resonance frequency. In some instances, the conductive segment 632 can be configured to generate a microwave magnetic field with a maximum field intensity at the center of the half-wave segments of the microstrip line resonators, for example, by using a half-wave resonator for each of the conductive segment 632. In some implementations, the conductive segments 632 can be edge-coupled to each other so that the magnetic field generated by each resonator interferes with the magnetic field generated by one or more neighboring conductive segments 632. In some cases, the conductive segments 632 produce an in-plane uniform field in a direction perpendicular to the surface of the substrate.

In the example shown in FIG. 6, a coupling gap 642A is defined between the first end of the conductive segments 632 and the respective terminal segments 624 of the first terminal 612A. Similarly, a coupling gap 642B is defined between the second end of the conductive segments 632 and the coupling segments 646 of the coupling transmission line resonator 606. The coupling gaps 642A, 642B can include vacuum, dielectric material (e.g., sapphire, silicon, quartz, etc.), or a combination of them. The terminal segments 624 in the first terminal 612 can serve as feed lines coupled to the array of conductive segments 632 via the coupling gap 642A. In some instances, during operation, all of the conductive segments 632 experience an electromagnetically equivalent feed line path from a pair of a terminal segment 624 of the first terminal 612A and a respective coupling segment 646 of the coupling transmission line resonator 606, and the conductive segments 632 of the primary transmission line resonator 602 can resonate in-phase at their fundamental frequency. Each conductive segment 632 is configured to resonate at a first intrinsic resonance frequency, and the length of the conductive segments 632 may be an even number of half-wavelengths for the first intrinsic resonance frequency; and the length of the conductive elements 632 may be an odd number of half-wavelengths for the first intrinsic resonance frequency.

As shown in FIG. 6, the coupling transmission line resonator 606 further includes a body 648 which includes a branching structure connected to the coupling segments 646 on one end and a transmission line structure 644 on the opposite end. The transmission line structure 644 is galvanically coupled to the coupling segments 646. A coupling gap 642C is defined between the transmission line structure 644 of the coupling transmission line resonator 606 and a first end of the auxiliary transmission line resonator 604; and a coupling gap 642D is defined between a second, opposite end of the auxiliary transmission line resonator 604 and the second terminal 612B of the microwave resonator device 600. In some instances, the coupling gaps 642C, 642D may be implemented as the coupling gaps 642A, 642B or in another manner.

As shown in FIG. 6, the first and second terminals 612A 612B, the primary, auxiliary and coupling transmission line resonators 602, 604, 606 each have a planar transmission line structure. Here “planar” is used broadly to describe structures that are substantially larger in one or both planar dimensions (length and width) than in their height dimension. In some instances, a planar structure has a height that is substantially uniform (e.g., compared to the overall length and width of the structure) over its planar extent. In some implementations, the planar transmission line structure can receive an input signal (e.g., electron spin resonance control signals through the first terminal 612A), conduct the signal across each of the parallel conductive segments 632 in the same direction in the primary transmission line resonator 602; and generate a microwave magnetic field in the sample region 650.

In some implementations, the first and second terminals 612A 612B, the primary, auxiliary and coupling transmission line resonators 602, 604, 606 are configured as superconducting transmission line resonators. The conducting material of the first and second terminals 612A 612B, the primary, auxiliary and coupling transmission line resonators 602, 604, 606, and ground plane can be made of superconducting material, such as, for example, niobium, niobium titanium, niobium nitride, aluminum, yttrium barium copper oxide (aka, “YBCO”), or another appropriate material. The conducting material of the first and second terminals 612A 612B, the primary, auxiliary and coupling transmission line resonators 602, 604, 606, and the ground plane can be made of other types of conducting material, such as, for example, non-superconducting materials including copper, gold, etc. The conducting materials can be deposited on the substrate by standard deposition techniques. The substrate can be etched or otherwise conditioned based on standard fabrication techniques. In certain instances, the substrate can be made of dielectric material such as, for example, sapphire, silicon, quartz, or another type of non-magnetic dielectric crystalline material.

In some implementations, the sample region 650 of the microwave resonator device 600 is located adjacent to the conductive segments 632 of the primary transmission line resonator 602. The sample region 650 can be a planar sample volume or another type of volume. In some instances, the magnetic field generated by the primary transmission line resonator 602 is uniform across the sample region 650. For example, the sample region 650 can include planes (parallel to the surface) over which the instantaneous magnetic field generated by the primary transmission line resonator 602 is homogeneous during operation. In some instances, the sample region 650 includes samples for ESR applications or experiments, or for additional or different applications. In some implementations, the samples can be thin planar samples, for example, Langmuir-Blodgett films or self-assembled monolayer films, polymer films, biological films, etc. Some example applications of the microwave resonator device 600 can include using the Langmuir Blodgett films or self-assembled monolayer films with free radicals for quantum computing, and using the biological films to, for example, label electrons and study membrane bound proteins using ESR. In some implementations, the sample volume is a region of given homogeneity interacting with the sample in the sample region. The sample can be positioned in the sample volume of the microwave resonator device 600. In some implementations, the primary transmission line resonator 602 has a greater sample volume than that of the auxiliary transmission line resonator 604. In some instances, since the sample volume of the auxiliary transmission line resonator 604 does not interact with the sample; the sample volume of the auxiliary transmission line resonator 604 is small for convenience.

In some implementations, the example microwave resonator device 600 and the sample can be positioned in an external, static primary magnetic field (B₀). The primary magnetic field can be parallel to the surface of the substrate. The primary magnetic field can polarize the electron spins in the sample. The electron spins have one or more resonance frequencies or a distribution of resonant frequencies (or spin precession frequencies) in the primary magnetic field. The resonance frequencies are typically in the GHz range (e.g., microwave frequencies) in ESR applications. In operation, the conductive segments 632 can generate a microwave magnetic field at the resonance frequencies of the electron spins to manipulate the electron spins simultaneously.

In some instances, for optimization of bandwidth, the quality factor of the microwave resonant modes can be controlled by varying the size of the coupling gaps 642A, 642B, 642C, 642D at the ends of each resonator, provided that the internal quality factor remains significantly higher than the external quality factor. The primary and auxiliary transmission line resonators 602, 604 are initially designed separately to ensure they share identical and desired intrinsic resonance frequencies and quality factors. In some instances, the auxiliary transmission line resonator 604 may have a second, distinct intrinsic resonance frequency; and the first and second intrinsic resonance frequencies of the primary and auxiliary transmission line resonators 602 and 604 may have a frequency detuning. The coupling transmission line resonator 606 can be then designed and optimized to create the desired microwave multi-mode resonant structure. The coupling transmission line resonator 606 hybridizes resonant behavior of the primary and auxiliary transmission line resonators 602, 604, such that the multiple microwave resonant modes are spatially dispersed over the primary and auxiliary transmission line resonators 602, 604.

In some instances, the microwave resonator device 600 can convert the electron spin resonance control signals to a microwave magnetic field in the sample region 650. In some implementations, the microwave magnetic field can be in-plane homogeneous in a sample region 650, such that the microwave magnetic field is uniform in planes crossing the sample region 650. This field can be substantially uniform in strength and occupy a small mode volume well matched to the volume of the sample. The microwave magnetic field can be applied to one or more samples in the sample region, for example, for pulsed ESR or multi-resonance ESR measurements.

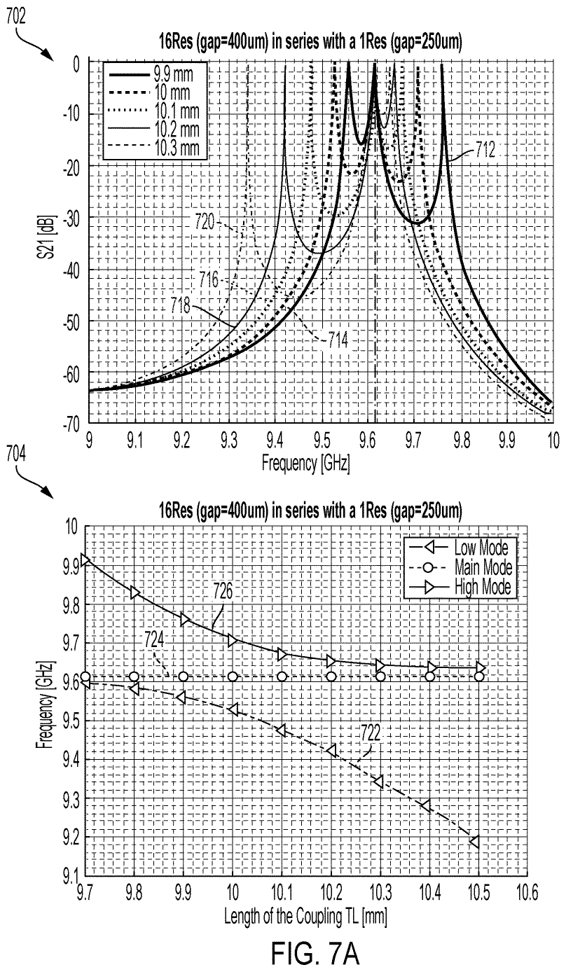

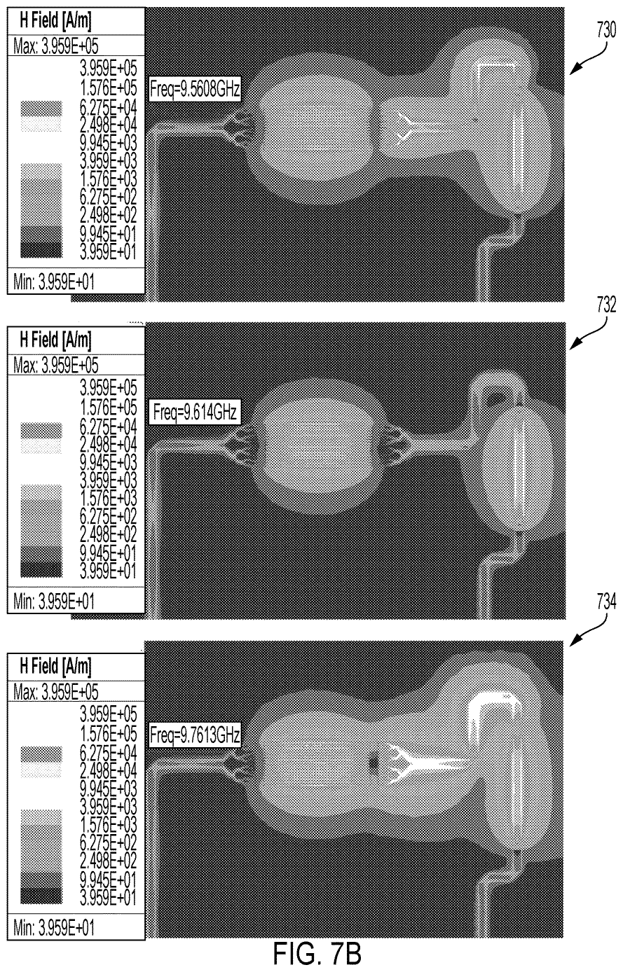

FIG. 7A includes a plot 702 showing S-parameters (S21) in dB as a function of frequency in GHz with the coupling transmission line resonator 606 in the example microwave resonator device 600 shown in FIG. 6 at different lengths; and a plot 704 showing frequency in GHz as a function of the length of the coupling transmission line resonator 606 at different microwave resonant modes. The substrate is R-cut sapphire with an anisotropic dielectric constant of (10.0078, 10.0078, 9.8643) and a thickness of 430 μm. All conductors are implemented as microstrip line resonators; and are treated as perfect electrical conductors (PECs). The conductive segments 632 in the primary transmission line resonator 602 have a length of 5150 μm, a width 40 μm, and a spacing of 100 μm appropriate for relatively large EPR samples. The microstrip line of the auxiliary transmission line resonator 604 has a length of 5720 μm and a width 400 μm which does not directly interact with the EPR sample at the sample region 650 of the microwave resonator device 600. The coupling gaps 642A, 642B are 400 μm for the primary resonator 602; and the coupling gaps 642C, 642D are 250 μm for the auxiliary resonator 604. The coupling transmission line resonator 606 also has a microstrip transmission line structure that itself acts as a resonator, leading to three microwave resonant modes.

As shown in plot 702 of FIG. 7A, by changing the lengths of the coupling transmission line resonator 606, the resonance frequencies of the microwave resonator device 600 and the frequency separations among the resonance frequencies can be tuned. Curve 712 corresponds to the length of the coupling transmission line resonator 604 of 9.9 mm; curve 714 corresponds to the length of the coupling transmission line resonator 604 of 10 mm; curve 716 corresponds to the length of the coupling transmission line resonator 604 of 10.1 mm; curve 718 corresponds to the length of the coupling transmission line resonator 604 of 10.2 mm; and curve 720 corresponds to the length of the coupling transmission line resonator 604 of 10.3 mm. As shown in plot 704 of FIG. 7A, the resonance frequencies of the low mode (curve 722) and the high mode (curve 726) reduce as the length of the coupling resonant device 606 increases from 9.7 mm to 10.5 mm; and the resonance frequency of the main mode (curve 724) remain relatively unchanged when the length of the coupling resonant device 606 increases from 9.7 mm to 10.5 mm.

FIG. 7B includes a plot 730 showing a spatial distribution of a magnetic field at a resonance frequency of 9.5608 GHz (low mode) in the microwave resonator device 600, a plot 732 showing a spatial distribution of a magnetic field at a resonance frequency of 9.614 GHz (main mode) in the microwave resonator device 600, and a plot 734 showing a spatial distribution of a magnetic field at a resonance frequency of 9.7613 (high mode) in the microwave resonator device 600. The length of the coupling transmission line resonator 606 is 9.9 mm. As shown in FIG. 7B, full-wave simulations verify that each of the three microwave resonant modes has an associated spatial magnetic field component at the primary transmission line resonator 602 used for electron spin resonance measurement. The three microwave resonant modes can be divided into two sets: the ‘main mode’ with a resonance frequency independent of coupling parameters and with spatial field components localized to the primary and auxiliary transmission line resonators 602, 604; and the ‘low mode’ and ‘high mode’ that vary with coupling parameter adjustment and contain spatial field components distributed across all three transmission line resonators 602, 604, 606. The orientation of the low and high modes varies in phase by 180 degrees, corresponding to opposite field directions at the same spatial location.

FIG. 8 is a schematic diagram showing aspects of an example microwave resonator device 800. As shown in FIG. 8, the microwave resonator device 800 includes a primary transmission line resonator 802 and an auxiliary transmission line resonator 804, which are coupled by a coupling transmission line resonator 806. The microwave resonator device 800 includes multiple conductors which are configured to collectively support multiple microwave resonant modes. The primary transmission line resonator 802 includes a first subset of conductors configured as an array of conductive segments 832; the auxiliary transmission line resonator 804 includes a second subset of conductors; and the coupling transmission line resonator 806 includes a third subset of conductors The example microwave resonator device 800 includes a first terminal 812A and a second terminal 812B. The terminals 812A, 812B, the primary transmission line resonator 802, the auxiliary transmission line resonator 804, and the coupling transmission line resonator 806 may be implemented, fabricated, and operated as respective components of the example microwave resonator device 600 shown in FIG. 6 or in another manner. The coupling transmission line resonator 806 has a longer length than that of the coupling transmission line resonator 606 in FIG. 6. The example microwave resonator device 800 can include additional or different features, and the features of the example microwave resonator device 800 may be arranged in the configuration shown or in another configuration.

In some implementations, the example microwave resonator device 800 can be operated according to the operations in the example process 1400 in FIG. 14 to produce a time-varying magnetic field with multiple microwave resonant modes in the GHz range (microwave frequencies) in a sample region 850 of the microwave resonator device 800. For example, the microwave resonator device 800 may produce a magnetic field with a radio frequency or microwave frequency configured to manipulate electron spins in the sample region 850 above the primary transmission line resonator 802. In some instances, the sample region 850 includes samples for ESR applications or experiments, or for additional or different applications. In some implementations, the samples can be thin planar samples, for example, Langmuir-Blodgett films or self-assembled monolayer films, polymer films, biological films, etc. Some example applications of the microwave resonator device 800 can include using the Langmuir-Blodgett films with free radicals for quantum computing, and using the biological films to, for example, label electrons and study membrane bound proteins using ESR.

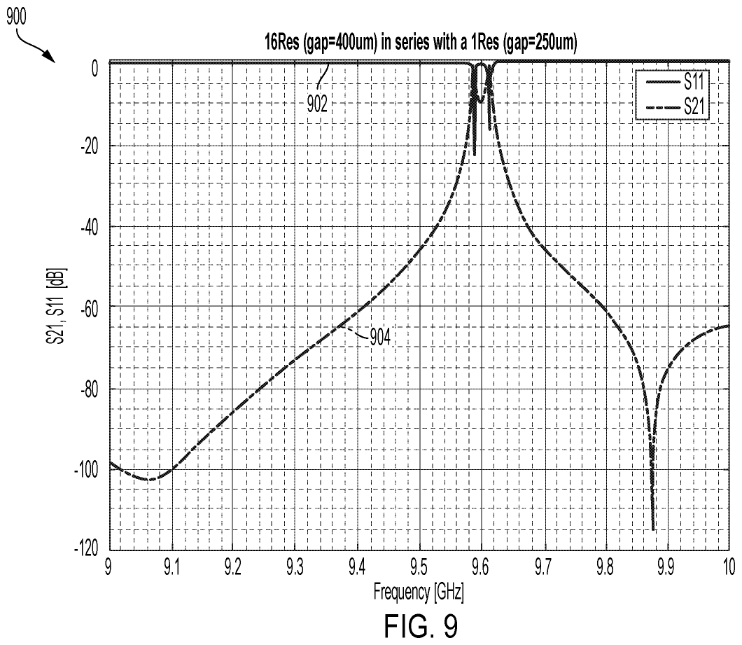

FIG. 9 is a plot 900 showing S-parameters (S11-curve 902 and S21-curve 904) in dB as a function of frequency in GHz in the example microwave resonator device 800 shown in FIG. 8. The substrate is R-cut sapphire with an anisotropic dielectric constant of (10.0078, 10.0078, 9.8643) and a thickness of 430 μm. The primary, auxiliary and coupling transmission line resonators 802, 804, 806 are implemented as microstrip line resonators; and the multiple conductors of the example microwave resonator device 800 are treated as perfect electrical conductors (PECs). The conductive segments 832 in the primary transmission line resonator 802 have a length of 5150 μm, a width of 40 μm, and a spacing of 100 μm appropriate for relatively large EPR samples. The microstrip line of the auxiliary transmission line resonator 804 has a length of 5720 μm and a width 400 μm which does not directly interact with the EPR sample at the sample region of the primary transmission line resonator 802. The coupling transmission line resonator 806 is also a microstrip line resonator having a length of 25.4 mm, which includes both branching and coupling segments. The width of the coupling gap 842B is 400 μm; and the width of the coupling gap 842C is 250 μm. As shown in FIG. 9, using the coupling transmission line resonator 806 with a longer length, the desired microwave resonant multi-mode structure includes two closely separated microwave resonant modes with one mode significantly detuned. The low mode resonance is not shown as it falls outside the frequency range of 9-10 GHz.

FIG. 10A is a circuit diagram showing an equivalent circuit model of an example microwave resonator device 1000. As shown in FIG. 10A, the example microwave resonator device 1000 includes a first single-mode resonator 1002A and a second single-mode resonator 1002B, which are coupled in series through a coupling capacitor 1004. As shown in FIG. 10A, each of the two single-mode resonators 1002A, 1002B includes an RLC resonator with a combination of a resistor (R), an inductor (L), and a capacitor (C) to resonate a specific intrinsic resonance frequency. In particular, the first single-mode resonator 1002A includes a first RLC resonator with a first resistor having a resistance of R₁, a first inductor having an inductance of L₁, and a first capacitor having a capacitance of C₁; and the second single-mode resonator 1002B includes a second RLC resonator with a second resistor having a resistance of R₂, a second inductor having an inductance of L₂, and a second capacitor having a capacitance of C₂. The coupling capacitor 1004 has a capacitance of Cₘ. In some instances, the first and second single-mode resonators 1002A, 1002B may have distinct intrinsic resonance frequencies, e.g., the first and second single-mode resonators 1002A, 1002B may be asynchronously tuned.

The coupling between the first and second single-mode resonator 1002A, 1002B through the coupling capacitor 1004 can cause a mixing or a hybridization of independent resonator modes to create multiple microwave resonant modes that spans both single-mode resonators 1002A, 1002B. In this configuration, an electron spin resonance sample is physically positioned near one of the resonators, e.g., the first single-mode resonator 1002A, known as the ‘primary resonator,’ with a greater sample volume than that of the second single-mode resonator 1002B, to allow exchange of magnetic field energy at two distinct frequencies. The second single-mode resonator 1002B, referred to as the ‘auxiliary resonator’, does not directly interact with the sample but instead serves to introduce additional microwave resonant modes in the first single-mode resonator 1002A.

FIG. 10B includes effective circuit diagrams 1030, 1040 showing modes of operation (Odd” and “Even” modes) of an example microwave resonator device 1020. As shown in FIG. 10B, the example microwave resonator device 1020 includes a first single-mode resonator 1022A and a second single-mode resonator 1022B, which are coupled in series through two coupling capacitors 1024A, 1024B. As shown in FIG. 10B, each of the two single-mode resonators 1022A, 1022B includes an RLC resonator with a combination of a resistor (R), an inductor (L), and a capacitor (C) to resonate a specific intrinsic resonance frequency. In particular, the first single-mode resonator 1022A and the second single-mode resonator 1022B are identical, each including an RLC resonator with a resistor having a resistance of R₀, an inductor having an inductance of L₀, and a capacitor having a capacitance of C₀. The coupling capacitors 1024A, 1024B each has a capacitance of 2Cₘ causing the equivalent total capacitance of Cₘ. In some instances, the first and second single-mode resonators 1022A, 1022B may be implemented and operated as the first and second single-mode resonators 422A, 4222B in FIG. 4B.

In some implementations, the first and second single-mode resonators 1022A, 1022B in FIG. 10B are synchronously tuned to resonate at the same resonance frequency. The circuit exhibits symmetry that permits an “Even” and “Odd” mode analysis based on the superposition theorem as shown in FIG. 10B. The Odd mode represented by a circuit diagram 1030 in FIG. 10B corresponds to an RLC resonator with a resistor having a resistance of R₀, an inductor having an inductance of L₀, and a capacitor having a capacitance of 2Cₘ+C₀. Conversely, the Even mode represented by a circuit diagram 1040 in FIG. 10B corresponds to an RLC resonator with a resistor having a resistance of R₀, an inductor having an inductance of L₀, and a capacitor having a capacitance of C₀.

FIG. 11A is a circuit diagram showing an equivalent circuit model of an example microwave resonator device 1100. As shown in FIG. 11A, the example microwave resonator device 1100 includes a first single-mode resonator 1102A and a second single-mode resonator 1102B, which are coupled in series through a coupling inductor 1104. As shown in FIG. 11A, each of the two single-mode resonators 1102A, 1102B includes an RLC resonator with a combination of a resistor (R), an inductor (L), and a capacitor (C) to resonate a specific intrinsic resonance frequency. In particular, the first single-mode resonator 1102A includes a first RLC resonator with a first resistor having a resistance of R₁, a first inductor having an inductance of L₁, and a first capacitor having a capacitance of C₁; and the second single-mode resonator 1102B includes a second RLC resonator with a second resistor having a resistance of R₂, a second inductor having an inductance of L₂, and a second capacitor having a capacitance of C₂. The coupling inductor 1104 is caused by a mutual inductance of Lₘ between the first and second inductors of the first and second single-mode resonators 1102A, 1102B.

The coupling between the first and second single-mode resonator 1102A, 1102B through the coupling inductor 1104 can cause a mixing or a hybridization of multiple independent microwave resonant modes to create a microwave resonant multi-mode structure that spans both single-mode resonators 1102A, 1102B. In this configuration, an electron spin resonance sample is physically positioned near one of the resonator devices 1102A, 1102B, e.g., the first single-mode resonator 1102A, known as the ‘primary resonator,’ with a greater sample volume than that of the second single-mode resonator 1102B, to allow exchange of magnetic field energy at two distinct resonance frequencies. The second single-mode resonator 1102B, referred to as the ‘auxiliary resonator’, does not directly interact with the sample but instead serves to introduce additional microwave resonant modes in the first single-mode resonator 1102A.

FIG. 11B includes effective circuit diagrams 1130, 1140 showing modes of operation of an example microwave resonator device 1120. As shown in FIG. 11B, the example microwave resonator device 1120 includes a first single-mode resonator 1122A and a second single-mode resonator 1122B, which are coupled in series through two coupling inductors 1124A, 1124B. As shown in FIG. 11B, each of the two single-mode resonators 1122A, 1122B includes an RLC resonator with a combination of a resistor, an inductor, and a capacitor to resonate a specific intrinsic resonance frequency. In particular, the first single-mode resonator 1122A and the second single-mode resonator 1022B are identical, each including an RLC resonator with a resistor having a resistance of R₀, an inductor having an inductance of L₀, and a capacitor having a capacitance of C₀.

In some implementations, the first and second single-mode resonators 1122A, 1122B in FIG. 11B are synchronously tuned to resonate at the same resonance frequency. The circuit exhibits symmetry that permits an “Even” and “Odd” mode analysis based on the superposition theorem as shown in FIG. 11B. The Odd mode represented by a circuit diagram 1130 in FIG. 11B corresponds to an RLC resonator with a resistor having a resistance of R₀, an inductor having an inductance of L₀−Lₘ, and a capacitor having a capacitance of C₀. Conversely, the Even mode represented by a circuit diagram 1140 in FIG. 11B corresponds to an RLC resonator with a resistor having a resistance of R₀, an inductor having an inductance of L₀+Lₘ, and a capacitor having a capacitance of C₀.

In some implementations, two microwave resonant modes are present using the microwave resonator devices 1000, 1020, 1100, 1120 in FIGS. 10A-10B and 11A-11B, with resonance frequencies determined from the following equations:

$$Event mode ( coupling capacitor ) : {ω}_{e} = \frac{1}{\sqrt{{L}_{0} {C}_{0}}} \qquad ( 14 )$$

$$Odd Mode ( coupling capacitor ) : {ω}_{o} = \frac{1}{\sqrt{{L}_{0} ( 2 {C}_{m} + {C}_{0} )}} \qquad ( 15 )$$

$$Even Mode ( coupling inductor ) : {ω}_{e} = \frac{1}{\sqrt{{C}_{0} ( {L}_{0} + {L}_{m} )}} \qquad ( 16 )$$

$$Odd Mode ( coupling inductor ) : {ω}_{o} = \frac{1}{\sqrt{{C}_{0} ( {L}_{0} - {L}_{m} )}} \qquad ( 17 )$$

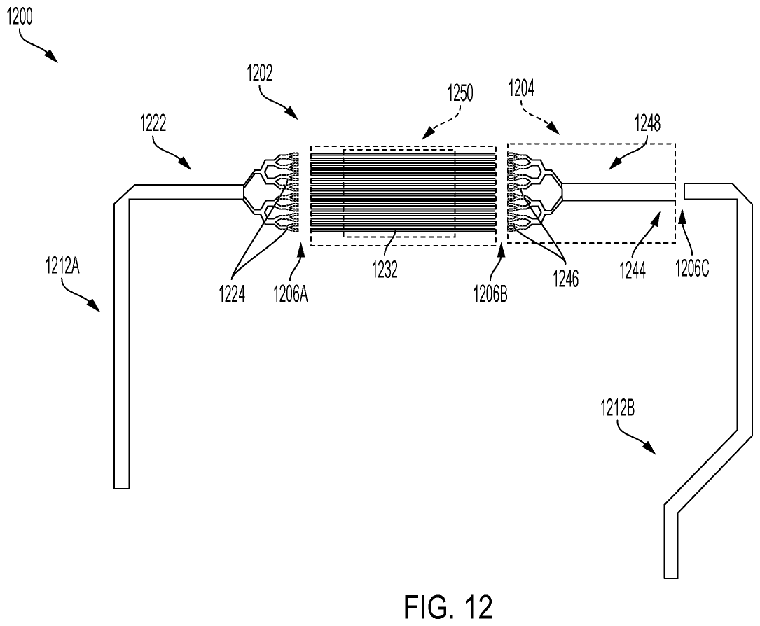

FIG. 12 is a schematic diagram showing aspects of an example microwave resonator device 1200. As shown in FIG. 12, the microwave resonator device 1200 includes a primary transmission line resonator 1202 and an auxiliary transmission line resonator 1204 separated by a coupling gap 1206. The microwave resonator device 1200 includes multiple conductors which are configured to collectively support multiple microwave resonant modes. The primary transmission line resonator 1202 includes a first subset of conductors configured as an array of conductive segments 1232; and the auxiliary transmission line resonator 1204 includes a second subset of conductors. The example microwave resonator device 1200 shown in FIG. 12 includes a first terminal 1212A and a second terminal 1212B. The first and second terminals 1212A, 1212B, the primary transmission line resonator 1202, and the auxiliary transmission line resonator 1204, and the ground plane can define microstrip resonators, coplanar waveguide resonators, or other types of planar transmission line resonators on a surface of a substrate. In some implementations, the first and second terminals 1212A, 1212B, and the primary transmission line resonator 1202 are implemented and operated as the respective components of the example microwave resonator device 600, 800 in FIGS. 6 and 8. The example microwave resonator device 1200 can include additional or different features, and the features of the example microwave resonator device 1200 may be arranged in the configuration shown or in another configuration.

In some implementations, the example microwave resonator device 1200 can be operated according to the operations in the example process 1400 shown in FIG. 14 to produce a time-varying magnetic field in a sample region 1250 above the primary transmission line resonator 1202. For example, the microwave resonator device 1200 may produce a magnetic field at a radio frequency or microwave frequency configured to manipulate electron spins in the sample region of the microwave resonator device 1200.

In the example shown in FIG. 12, a coupling gap 1206A is defined between a first end of the conductive segments 1232 of the primary transmission line resonator 1202 and respective terminal segments 1224 of the first terminal 1212A. Similarly, a coupling gap 1206B is defined between a second end of the conductive segments 1232 of the primary transmission line resonator 1202 and respective conductive segments 1246 of the auxiliary transmission line resonator 1204. The coupling gaps 1206A, 1206B can include vacuum, dielectric material (e.g., sapphire, silicon, quartz, etc.), or a combination of them. As shown in FIG. 12, the auxiliary transmission line resonator 1204 further includes a body 1248 which includes a branching structure galvanically connected to the conductive segments 1246 on one end and a transmission line structure 1244 on the opposite end. A coupling gap 1206C is defined between the transmission line structure 1244 of the auxiliary transmission line resonator 1204 and the second terminal 1212B of the microwave resonator device 1200. In some instances, the coupling gap 1206C may be implemented as the coupling gaps 1206A, 1206B or in another manner. In some instances, for optimization of bandwidth, the quality factor of the microwave resonant modes can be controlled by varying the size of the coupling gaps 1206A, 1206B, 1206C at the respective ends of the transmission line resonators 1202, 1204, provided that the internal quality factor remains significantly higher than the external quality factor.

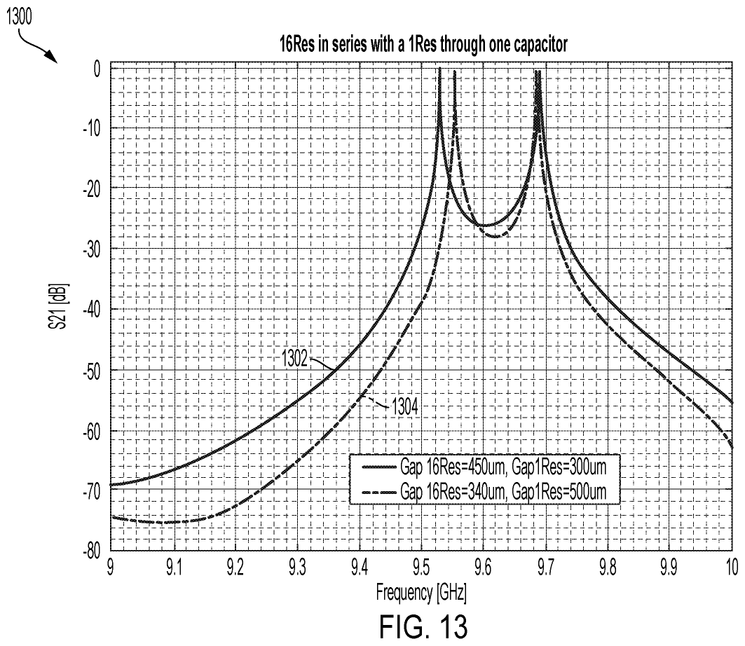

FIG. 13 is a plot 1300 showing S-parameters (S21) in dB as a function of frequency in GHz at different sizes of the coupling gaps 1206B, 1206C in the microwave resonator device 1200 shown in FIG. 12. The substrate is R-cut sapphire with an anisotropic dielectric constant of (10.0078, 10.0078, 9.8643) and a thickness of 430 μm. Each of the multiple conductors is implemented as a microstrip line resonator; and all the conductors are treated as perfect electrical conductors (PECs). The conductive segments 1232 in the primary transmission line resonator 1202 have a length of 5150 μm and a width 40 μm appropriate for relatively large samples. The microstrip line of the auxiliary transmission line resonator 1204 has a length of 5720 μm and a width 400 μm which does not directly interact with the sample at the sample region 1250 of the primary transmission line resonator 1202.

As shown in FIG. 13, by changing the sizes of the coupling gaps 1206B, 1206C, the resonant modes and the frequency separations between the resonant modes can be tuned. Curve 1302 corresponds to a size of the coupling gap 1206B of 450 μm and a size of the coupling gap 1206C of 300 μm; and curve 1304 corresponds to a size of the coupling gap 1206B of 340 μm and a size of the coupling gap 1206C of 500 μm.

FIG. 14 is a flow chart showing aspects of an example process 1400 for operating a microwave resonator device. The example process 1400 can be used for performing an electron spin resonance process by operation of a microwave resonator device. In some implementations the microwave resonator device includes a primary transmission line resonator and an auxiliary transmission line resonator coupled to the primary transmission line resonator. In some instances, the primary transmission line resonator includes a single microstrip resonator, multiple microstrip resonators, a single coplanar waveguide resonator, or another type of transmission line resonator; and the auxiliary transmission line resonator includes a single microstrip resonator, multiple microstrip resonators, a single coplanar waveguide resonator, or another type of transmission line resonator. In some instances, the primary and auxiliary transmission line resonators may have different transmission line structures. In some implementations, the microwave resonator device may be implemented as the example microwave resonator devices 600, 800, 1200 shown in FIGS. 6, 8, 12, or another type of resonator device.

In some implementations, the microwave resonator device is designed to support multiple microwave resonant modes. The operations of the example process 1400 may be performed by operation of the electron spin resonance system 100 in FIG. 1. The example process 1400, individual operations of the process 1400, or groups of operations may be iterated or performed simultaneously to achieve a desired result. In some cases, the example process 1400 may include the same, additional, fewer, or different operations performed in the same or a different order.

In some implementations, modulated pulses are used in multiple resonance measurements. The modulated pulses are applied at several independent and distinct carrier frequencies to create and measure the evolution of multi-spin correlated states over a large spectral bandwidth. In some instances, to minimize undesirable measurement artifacts generated by interference between frequency channels, pulse bandwidths may be designed to have minimal spectral overlap between channels. In certain instances, frequency channels may be implemented in a magnetic resonance spectrometer either as a multiplexed signal transmitted through a single high-bandwidth hardware channel, or as a set of signals with distinct carrier frequencies transmitted through separate hardware channels. In some instances, a combination of the two approaches in a single system may be used. In some implementations, one or more of the operation frequencies are generally assigned as an observer frequency for measuring and demodulating detectable spin coherence. In some instances, the corresponding carrier frequencies may be demodulated by operation of a detection system. The mode structure of a resonator device is used to transmit multiple resonance pulses to a spin system and detect the resulting spin signal which may have at least one of two characteristics: a single resonance mode with sufficient bandwidth to transmit and detect signals at all carrier frequencies simultaneously; or multiple resonance modes that each correspond to one or more carrier frequencies to be used in the pulse sequence.

At 1402, a sample is positioned at a sample region of the microwave resonator device. In some instances, a sample containing an ensemble of electron spins can be placed in a static, external magnetic field, and the external magnetic field can (at least partially) polarize the ensemble and define a resonance frequency of the electron spins. The sample can be positioned in a sample region of the microwave resonator device (e.g., the sample region 650, 850, 1250 above the primary transmission line resonator 602, 802, 1202 in FIGS. 6, 8, 12). In some instances, the geometrical parameters of the microwave resonator device can be designed according to the electron spin systems to be measured. For example, a sample may be a biological sample (e.g., a blood sample, a urine sample, a saliva sample, a sweat sample, or another type of biological sample). In some implementations, the samples can be thin planar samples, for example, Langmuir-Blodgett films or self-assembled monolayer films, polymer films, biological films, etc. In some instances, a sample may be preprocessed, e.g., attaching molecules containing paramagnetic centers as spin labels to specific sites on the biomolecule of interest.

In some implementations, multiple resonance measurements are used in pulsed electron paramagnetic resonance (EPR) to examine the nature of multi-spin coupling networks in samples containing multiple unpaired electron spins. In contrast to single resonance measurements, microwave pulses are applied in a sequence at multiple frequencies across the spin resonance spectrum to create correlated multi-spin states whose evolution under the coupling network is then monitored. The most common class of multiple resonance measurements are double resonance (DEER or PELDOR) measurements that examine pairwise interactions of electron spins. A series of pulses at two or more distinct frequencies are applied to the microwave resonator device. The multiple frequencies include a ‘probe’ frequency that creates observable coherence that evolves under pairwise couplings and is detected; and a pump frequency that that serves to refocus pairwise couplings at varying times to reveal a distribution of coupling strengths of the pairwise couplings.

At 1404, two or more frequency channels are defined as a set of modulated pulses with distinct carrier frequencies. In some implementations, the carrier frequency can be in the microwave frequency, e.g., in a range of 2 to 90 GHz. In some instances, the carrier frequencies of the pulsed microwave signal are determined according to one of the multiple microwave resonant modes of the resonator device. For example, if the microwave resonator device has multiple resonance frequencies in a range of 9-10 GHz, the carrier frequency of the pulsed microwave signal may be in the same range. A set of pulses with distinct carrier frequencies can be modulated; and modulated pulses define respective frequency channels.

At 1406, the frequency channels are assigned to one or more control hardware channels. The control system 114 can generate a hardware control sequence corresponding to the modulated pulses; and corresponding hardware control signals of the modulated pulses are determined according to the frequency and bandwidth of hardware channels in the computer and signal processing unit 102, e.g., DAC (digital to analog converter) channels, ADC (analog to digital converter) channels, DIO (digital input/output) channels, transmitter and receiver of the spectrometer 104, and possibly other control hardware channels. . . . For example, a respective control hardware channel needs to have a sufficient bandwidth to cover a respective pulse bandwidth. Corresponding hardware control signals for controlling output of respective control hardware channels can be generated, by operation of the control system 114.

At 1408, the frequency channels are assigned to one or more resonant modes of the resonator device. In some instances, the resonance modes need to have sufficient bandwidths to cover the pulse bandwidths of the pulses in the pulse sequence.

In some instances, the pulsed microwave signal is generated externally (e.g., external to the microwave resonator device) and provided to the resonator device through one or more leads on the microwave resonator device. For example, the pulsed microwave signal can be generated by external electronics that are connected to the terminals of the microwave resonator device by operation of the control system 114 of the electron spin resonance system 100 in FIG. 1. As an example, the pulsed microwave signal can be received at the first terminals 612A, 812A, 1212A of the example microwave resonator devices 600, 800, 1200 shown in FIGS. 6, 8, 12. The first terminals 612A, 812A, 1212A deliver the pulsed microwave signal to the microwave resonator devices 600, 800, 1200 shown in FIGS. 6, 8, 12.

The pulsed microwave signal is provided to the primary transmission line resonator and the auxiliary transmission line resonator of the microwave resonator device. When the primary transmission line resonator includes multiple microstrip line resonators, the pulsed microwave signal can be delivered in-phase to each of the multiple microstrip line resonators of the primary transmission line resonator. In this case, all of the multiple microstrip line resonators can simultaneously receive the same signal with a common phase at each location on the conductive segments. As such, the phase of the signal on each conductive segment in the primary transmission line resonator can be substantially identical at each instant in time.

In some implementations, the pulsed microwave signal is further provided to the auxiliary transmission line resonator. The pulsed microwave signal can be provided from second opposite ends of the conductive segments of the primary transmission line resonator to the auxiliary transmission line resonator. For example, when the primary transmission line resonator and the auxiliary transmission line resonator are coupled to each through a coupling transmission line resonator, the pulsed microwave signal can be provided from the primary transmission line resonator to the auxiliary transmission line resonator via the coupling transmission line resonator (e.g., the primary transmission line resonator 602, 802 are coupled to the auxiliary resonator device 604, 804 via the coupling transmission line resonator 606, 806 in the microwave resonator device 600, 800 shown in FIGS. 6 and 8). In particular, the pulsed microwave signal can be provided by a capacitive coupling between respective second opposite ends of the conductive segments of the primary transmission line resonator and respective coupling segments on a first end the coupling transmission line resonator (e.g., the conductive segments 632, 832, 1232 of the primary transmission line resonator 602, 802, 1202 are capacitively coupled to the coupling segments 646, 846 of the coupling transmission line resonator 606 via the coupling gaps 642B, 842B as shown in FIGS. 6, 8); and further by a capacitive coupling between a second opposite end of the coupling transmission line resonator and the auxiliary transmission line resonator (e.g., the transmission line structure 644, 844 of the coupling transmission line resonator 606, 806 are capacitively coupled to the transmission line of the auxiliary transmission line resonator 604, 804 in the microwave resonator device 600, 800 as shown in FIGS. 6, 8). In some implementations, the coupling transmission line resonator can also introduce a third microwave resonant mode.

For another example, when the primary transmission line resonator and the auxiliary transmission line resonator are coupled through a coupling capacitor, pulsed microwave signal can be directly provided from the primary transmission line resonator to the auxiliary transmission line resonator via the coupling capacitor (e.g., the primary transmission line resonator 1202 and the auxiliary transmission line resonator 1204 are coupled via a coupling capacitor defined by the coupling gap 1206B in the microwave resonator device 1200 as shown in FIG. 12).

In some implementations, communicating the pulsed microwave signal from the first terminal to the second terminal across the coupled primary and auxiliary transmission line resonators can create a multi-mode structure that spans both of the primary and auxiliary transmission line resonators. The primary transmission line resonator is configured to generate microwave magnetic fields (e.g., drive magnetic fields) in a sample region to allow exchange of magnetic field energy at the first resonance frequency according to the pulsed microwave signal received. In some instances, the auxiliary transmission line resonator does not directly interact with the sample in the sample region; and is configured to introduce one or more additional microwave resonant modes in the primary transmission line resonator. In some instances, the primary and auxiliary transmission line resonators may have the same resonance frequency with or without a small amount of detuning, the different microwave resonant modes and frequency separates may be introduced to the sample region by tuning the design parameters of the coupling transmission line resonator and the coupling gaps. In some instances, the primary and auxiliary transmission line resonator may have different resonance frequencies. In this case, the different microwave resonant modes and frequency separates may be introduced to the sample region at the primary transmission line resonator according to the different resonance frequencies of the primary and auxiliary transmission line resonators and the design parameters of the coupling transmission line resonator and the coupling gaps.

For example, the primary transmission line resonator of the microwave resonator device can convert the pulsed microwave signal to a microwave magnetic field in the sample region. The magnetic field is generated over the sample region of the microwave resonator device (e.g., above the primary transmission line resonator). In some implementations, the magnetic field can be in-plane homogeneous in a sample region (e.g., a planar sample region), such that the magnetic field is uniform in planes crossing the sample region. This magnetic field can be substantially uniform in strength and occupies a small mode volume well matched to the volume of the sample. The generated magnetic field can be applied to one or more samples in the sample region, for example, for pulsed ESR.

In some instances, the microwave magnetic field at multiple distinct carrier frequencies can be used to manipulate the electron spins in the sample volume. The resonance frequencies of the magnetic field produced by the microwave resonator device can be designed, tuned, or otherwise controlled according to the resonance frequencies of the electron spins in the sample, and the design parameters of the microwave resonator device (e.g., width of coupling gaps, electrical length of conductors, etc.). In some implementations, the duration and power of the microwave magnetic field can be specified to rotate the electron spins by a particular angle. In some instances, there may be electron spins that have different resonance frequencies in a given sample, and the multiple frequencies of the magnetic field can be tuned to simultaneously detect EPR signals from different types of paramagnetic centers or from different orientations of the same type of paramagnetic center in a sample. In this case, the pulsed microwave signal communicated to the microwave resonator device may include a third resonance frequency component, which can be used to generate a microwave magnetic field at the third, distinct resonance frequency to interact with the different types of paramagnetic centers or the same type of paramagnetic center with different orientations.

At 1410, at least one of the defined frequency channels is designated as an observe frequency. In some instances, the magnetic resonance detection signal, e.g., electron spin signals, from all resonance modes may be received and detected simultaneously. In some implementations, the magnetic resonance detection signal at the observe frequency from the microwave resonator device can be demodulated by operation of the spectrometer 104. In some instances, during the multiple resonance measurement, the demodulated magnetic resonance detection signals from all resonance modes may be processed in parallel. The demodulated magnetic resonance detection signal can be processed for measurement, for pulse transient control and correction, or for other purposes.

In a general aspect of what is described above, a microwave resonator device for electron spin resonance is presented.

In a first example, a microwave resonator device for electron spin resonance includes a substrate; a ground plane on the substrate; a plurality of conductors that support a plurality of microwave resonant modes in a sample region of the microwave resonator device. The plurality of conductors are disposed on the substrate and include a first transmission line resonator; and a second transmission line resonator coupled to the first transmission line resonator.

Implementations of the first example may include one or more of the following features. The plurality of conductors includes a coupling network that couples the first transmission line resonator to the second transmission line resonator. The coupling network includes a third transmission line resonator capacitively coupled to the first and second transmission line resonators. The first transmission line resonator includes a plurality of elongated conductors. The third transmission line resonator includes a branching structure which includes a plurality of conductive segments. Each of the plurality of elongated conductors is capacitively coupled to a respective one of the plurality of conductive segments. The second transmission line resonator includes a single elongated conductor. The third transmission line resonator includes a transmission line structure that is galvanically connected to the branching structure. The transmission line structure is capacitively coupled to the single elongated conductor of the second transmission line resonator.

Implementations of the first example may include one or more of the following features. The first transmission line resonator includes a plurality of elongated conductors. The second transmission line resonator includes a branching structure which includes a plurality of conductive segments, and a transmission line structure that is galvanically connected to the branching structure; and each of the elongated conductors is coupled to a respective one of the plurality of conductive segments. Each of the plurality of elongated conductors is capacitively coupled to a respective one of the plurality of conductive segments through a respective coupling gap.

Implementations of the first example may include one or more of the following features. The first transmission line resonator includes a plurality of microstrip resonators each having a first microwave resonance frequency. The plurality of microstrip resonators are parallel to each other, with equal spacing between each neighboring pair of microstrip resonators. Each microstrip resonator of the first transmission line resonator includes a half-wave resonator, a full-wave resonator, or a multi-half-wave resonator.

Implementations of the first example may include one or more of the following features. The first transmission line resonator includes a single microstrip resonator having a first microwave resonance frequency. The first transmission line resonator includes a single coplanar waveguide resonator each having a first microwave resonance frequency. The plurality of conductors are made of superconducting material. The plurality of conductors is made of one or more non-superconducting metals. The plurality of conductors supports two microwave resonant modes with resonant frequencies in a frequency range of 2-90 GHz. The plurality of conductors supports three microwave resonant modes with resonant frequencies in a frequency range of 2-90 GHz. The first transmission line resonator has a sample volume greater than that of the second transmission line resonator.

Implementations of the first example may include one or more of the following features. The first transmission line resonator is a primary resonator that is configured to directly interact with a sample in the sample region. The primary resonator has a first microwave resonance frequency and is disposed on a first area of the substrate that is adjacent to the sample region. The second transmission line resonator is an auxiliary resonator that is configured to introduce an additional microwave resonant mode in the primary resonator. The auxiliary resonator has a second microwave resonance frequency and is disposed on a second area of the substrate that is offset from the first area of the substrate.

Implementations of the first example may include one or more of the following features. The first and second microwave frequencies are the same microwave frequency. The first and second microwave frequencies are distinct microwave frequencies. The second transmission line resonator is coupled to the first transmission line resonator by a coupling transmission line resonator that hybridizes resonant behavior of the first and second transmission line resonators, such that the plurality of microwave resonant modes are spatially dispersed over the first and second transmission line resonators.

In a second example, an electron spin resonance (ESR) system includes the microwave resonator device of the first example, and a control system configured to operate the microwave resonator device to perform multiple resonance measurements of electron spins in the sample region.

Implementations of the second example may include one or more of the following features. The control system is configured to operate the microwave resonator device to perform double resonance measurements of the electron spins in the sample region. The control system is configured to operate the microwave resonator device to produce, in the sample region, a probe frequency that creates observable coherence that evolves under pairwise couplings of the electron spins; and a pump frequency that refocuses pairwise interactions at varying times to reveal a distribution of coupling strengths of the pairwise couplings. The control system is configured to operate the microwave resonator device to perform Double Electron-Electron Resonance (DEER) or Pulse Electron Double Resonance (PELDOR) spectroscopy. The control system includes a computer system, signal processing units, and a spectrometer. The ESR system further includes a primary magnet system that generates a primary magnetic field in the sample region.

In a third example, a method of conducting an electron spin resonance measurement includes positioning a sample in a sample region of the microwave resonator device of the first example, causing the microwave resonator device to operate at a first resonance frequency; and causing the microwave resonator device to operate at a second resonance frequency.

While this specification contains many details, these should not be understood as limitations on the scope of what may be claimed, but rather as descriptions of features specific to particular examples. Certain features that are described in this specification or shown in the drawings in the context of separate implementations can also be combined. Conversely, various features that are described or shown in the context of a single implementation can also be implemented in multiple embodiments separately or in any suitable subcombination.

Similarly, while operations are depicted in the drawings in a particular order, this should not be understood as requiring that such operations be performed in the particular order shown or in sequential order, or that all illustrated operations be performed, to achieve desirable results. In certain circumstances, multitasking and parallel processing may be advantageous. Moreover, the separation of various system components in the implementations described above should not be understood as requiring such separation in all implementations, and it should be understood that the described program components and systems can generally be integrated together in a single product or packaged into multiple products.

A number of examples have been described. Nevertheless, it will be understood that various modifications can be made. Accordingly, other examples are within the scope of the following claims.

1. A microwave resonator device for electron spin resonance, the microwave resonator device comprising:
a substrate;
a ground plane on the substrate;
a plurality of conductors that support a plurality of microwave resonant modes in a sample region of the microwave resonator device, the plurality of conductors disposed on the substrate and comprising:
a first transmission line resonator; and
a second transmission line resonator coupled to the first transmission line resonator.

2. The microwave resonator device of claim 1, wherein the plurality of conductors comprises:
a coupling network that couples the first transmission line resonator to the second transmission line resonator.

3. The microwave resonator device of claim 2, wherein the coupling network comprises:
a third transmission line resonator capacitively coupled to the first and second transmission line resonators.

4. The microwave resonator device of claim 3, wherein the first transmission line resonator comprises a plurality of elongated conductors, the third transmission line resonator comprises a branching structure comprising a plurality of conductive segments, and each of the plurality of elongated conductors is capacitively coupled to a respective one of the plurality of conductive segments.

5. The microwave resonator device of claim 4, wherein the second transmission line resonator comprises a single elongated conductor, the third transmission line resonator comprises a transmission line structure that is galvanically connected to the branching structure, and the transmission line structure is capacitively coupled to the single elongated conductor of the second transmission line resonator.

6. The microwave resonator device of claim 1, wherein:
the first transmission line resonator comprises a plurality of elongated conductors;
the second transmission line resonator comprises:
a branching structure comprising a plurality of conductive segments, and
a transmission line structure that is galvanically connected to the branching structure; and
each of the elongated conductors is coupled to a respective one of the plurality of conductive segments.

7. The microwave resonator device of claim 6, wherein each of the plurality of elongated conductors is capacitively coupled to a respective one of the plurality of conductive segments through a respective coupling gap.

8. The microwave resonator device of claim 1, wherein the first transmission line resonator comprises a plurality of microstrip resonators each having a first microwave resonance frequency.

9. The microwave resonator device of claim 8, wherein the plurality of microstrip resonators are parallel to each other, with equal spacing between each neighboring pair of microstrip resonators.

10. The microwave resonator device of claim 8, wherein each microstrip resonator of the first transmission line resonator comprises a half-wave resonator, a full-wave resonator, or a multi-half-wave resonator.

11. The microwave resonator device of claim 1, wherein the first transmission line resonator comprises a single microstrip resonator having a first microwave resonance frequency.

12. The microwave resonator device of claim 1, wherein the first transmission line resonator comprises a single coplanar waveguide resonator each having a first microwave resonance frequency.

13. The microwave resonator device of claim 1, wherein the plurality of conductors are made of superconducting material.

14. The microwave resonator device of claim 1, wherein the plurality of conductors are made of one or more non-superconducting metals.

15. The microwave resonator device of claim 1, wherein the plurality of conductors supports two distinct microwave resonant modes that have respective resonance frequencies in a frequency range of 2-90 GHz.

16. The microwave resonator device of claim 1, wherein the plurality of conductors supports three distinct microwave resonant modes that have respective resonance frequencies in a frequency range of 2-90 GHz.

17. The microwave resonator device of claim 1, wherein the first transmission line resonator has a sample volume greater than that of the second transmission line resonator.

18. The microwave resonator device of claim 1, wherein:
the first transmission line resonator is a primary resonator that is configured to directly interact with a sample in the sample region, the primary resonator has a first microwave resonance frequency and is disposed on a first area of the substrate that is adjacent to the sample region; and
the second transmission line resonator is an auxiliary resonator that is configured to introduce an additional microwave resonant mode in the primary resonator, the auxiliary resonator has a second microwave resonance frequency and is disposed on a second area of the substrate that is offset from the first area of the substrate.

19. The microwave resonator device of claim 18, wherein the first and second microwave resonance frequencies are the same microwave frequency.

20. The microwave resonator device of claim 18, wherein the first and second microwave resonance frequencies are distinct microwave frequencies.

21. The microwave resonator device of claim 1, wherein the second transmission line resonator is coupled to the first transmission line resonator by a coupling transmission line resonator that hybridizes resonant behavior of the first and second transmission line resonators, such that the plurality of microwave resonant modes are spatially dispersed over the first and second transmission line resonators.

22. An electron spin resonance (ESR) system comprising:
a microwave resonator device comprising:
a substrate;
a ground plane on the substrate;
a plurality of conductors that support a plurality of microwave resonant modes in a sample region of the microwave resonator device, the plurality of conductors disposed on the substrate and comprising:
a first transmission line resonator; and
a second transmission line resonator coupled to the first transmission line resonator; and
a control system configured to operate the microwave resonator device to perform multiple resonance measurements of electron spins in the sample region.

23. The ESR system of claim 22, wherein the control system is configured to operate the microwave resonator device to perform double resonance measurements of the electron spins in the sample region.

24. The ESR system of claim 23, wherein the control system is configured to operate the microwave resonator device to produce, in the sample region:
a probe frequency that creates observable coherence that evolves under pairwise couplings of the electron spins; and
a pump frequency that refocuses pairwise interactions at varying times to reveal a distribution of coupling strengths of the pairwise couplings.

25. The ESR system of claim 23, wherein the control system is configured to operate the microwave resonator device to perform Double Electron-Electron Resonance (DEER) or Pulse Electron Double Resonance (PELDOR) spectroscopy.

26. The ESR system of claim 22, wherein the control system comprises a computer system, signal processing units, and a spectrometer.

27. The ESR system of claim 26, comprising a primary magnet system that generates a primary magnetic field in the sample region.

28. A method of conducting an electron spin resonance measurement, the method comprising:
positioning a sample in a sample region of a microwave resonator device, the microwave resonator device comprising:
a substrate;
a ground plane on the substrate;
a plurality of conductors that support a plurality of microwave resonant modes in a sample region of the microwave resonator device, the plurality of conductors disposed on the substrate and comprising:
a first transmission line resonator; and
a second transmission line resonator coupled to the first transmission line resonator;
causing the microwave resonator device to operate at a first resonance frequency;
causing the microwave resonator device to operate at a second resonance frequency; and
causing the microwave resonator device to obtain a spin signal response at one or both of the first and second resonance frequencies.
